(19) United States
(12) Patent Application Publication
(10) Pub. No.: US 2023/0326799 A1
(43) Pub. Date: Oct. 12, 2023

(54) WAVY-SHAPED EPITAXIAL SOURCE/DRAIN STRUCTURES

(71) Applicant: Taiwan Semiconductor Manufacturing Company, Ltd., Hsin-Chu (TW)

(72) Inventors: Shahaji B. More, Hsinchu City (TW); Cheng-Wei Chang, Taipei City (TW)

(21) Appl. No.: 17/815,884

(22) Filed: Jul. 28, 2022

Related U.S. Application Data
(60) Provisional application No. 63/328,526, filed on Apr. 7, 2022.

(51) Int. Cl. H01L 21/8234; H01L 27/088; H01L 29/78; H01L 29/08; H01L 29/417; H01L 29/66

(52) U.S. Cl. CPC H01L 21/823425; H01L 27/0886; H01L 21/823431; H01L 29/66795; H01L 29/785; H01L 29/0847; H01L 29/41791; H01L 21/823475

(57) ABSTRACT

Wavy-shaped epitaxial source/drain structures for multigate devices and methods of fabrication thereof are disclosed herein. An exemplary device includes a first fin and a second fin extending lengthwise along a first direction. The first fin and the second fin each have a non-recessed portion and a recessed portion. A gate extends lengthwise along a second direction that is different than the first direction. The gate wraps the non-recessed portion of the first fin and the non-recessed portion of the second fin. A merged epitaxial source/drain is on the recessed portion of the first fin and the recessed portion of the second fin. A source/drain contact is on the merged epitaxial source/drain. The source/drain contact and the merged epitaxial source/drain have a V-shaped interface therebetween. The source/drain contact extends below tops of the non-recessed portions of the first fin and the second fin.

This application is a non-provisional application of and claims benefit of U.S. Provisional Patent Application Ser. No. 63/328,526, filed Apr. 7, 2022, the entire disclosure of which is incorporated herein by reference.

### BACKGROUND

Multigate devices include a gate structure that extends, partially or fully, around a channel region to provide access to the channel region on at least two sides. Exemplary multigate devices include fin-like field effect transistors (FinFETs) and gate-all around (GAA) transistors, such as nanowire transistors. Multigate devices enable aggressive scaling down of IC technologies, maintaining gate control, and mitigating short-channel effects (SCEs), while seamlessly integrating with conventional IC manufacturing processes. However, as multigate devices continue to scale, epitaxial source/drain structures are needed for facilitating smaller IC feature sizes and denser packing of IC features for advanced IC technology nodes.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is fragmentary perspective view of a multigate device, in portion or entirety, according to various aspects of the present disclosure.

FIGS. 2A-2H are fragmentary cross-sectional views of a multigate device, in portion or entirety, at various fabrication stages according to various aspects of the present disclosure.

FIG. 3 is an enlarged view of the multigate device, in portion or entirety, at the fabrication stage of FIG. 2E according to various aspects of the present disclosure.

FIG. 4 is an enlarged view of the multigate device, in portion or entirety, at the fabrication stage of FIG. 2H according to various aspects of the present disclosure.

FIG. 5 is an enlarged view of the multigate device, in portion or entirety, at the fabrication stage of FIG. 2H according to various aspects of the present disclosure.

FIG. 6 is a fragmentary cross-sectional view of another multigate device, in portion or entirety, according to various aspects of the present disclosure.

FIG. 7 is a flow chart of a method for fabricating a multigate device having enhanced epitaxial source/drain structures according to various aspects of the present disclosure.

### DETAILED DESCRIPTION

The present disclosure relates generally to integrated circuit (IC) devices, and more particularly, to epitaxial source/drain structures for multigate devices, such as fin-like field-effect transistors (FETs) and/or gate-all-around (GAA) FETs, and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

An exemplary method for forming a wavy-shaped epitaxial source/drain structure is disclosed herein. The exemplary method includes etching back a first semiconductor fin to form a first source/drain recess and a second semiconductor fin to form a second source/drain recess, epitaxially growing a first semiconductor layer from the etched back first semiconductor fin and a first semiconductor layer from the etched back second semiconductor fin, epitaxially growing and merging second epitaxial layers from the first semiconductor layers, and epitaxially growing a third epitaxial layer from the merged second epitaxial layers. Various parameters of epitaxially growing the second epitaxial layers are tuned/configured to provide the merged second epitaxial layers with a wavy top surface, such as deposition/growth time, deposition/growth temperature, deposition/growth pressure, precursor flow rate, precursor concentration, precursor type, other parameter, or combinations thereof. Various parameters of epitaxially growing the second epitaxial layers are also tuned/configured to provide the wavy-shaped epitaxial source/drain structures with dimensions and/or content that optimize and/or balance contact area between the epitaxial source/drain structure and a subsequently formed source/drain contact, strain imparted by the wavy-shaped epitaxial source/drain structures on channel regions, etc.

In some embodiments, the merged second epitaxial layers form a trough (concave recess) of the wavy-shaped epitaxial source/drain structure. The trough can be U-shaped, V-shaped, or other suitable shape. A subsequently formed source/drain contact fills the trough, such that the source/drain contact and the wavy-shaped epitaxial source/drain structure have a concave interface therebetween. In some embodiments, the wavy-shaped epitaxial source/drain structure (in particular, the merged second epitaxial layers) wrap a bottom portion of the source/drain contact. The source/drain contact can be formed by forming a source/drain contact opening in a dielectric layer that exposes the trough of the wavy-shaped epitaxial source/drain structure, enlarging the trough, forming a silicide layer over the second epitaxial layers (which may include converting portions of the second epitaxial layers into the silicide layer), and forming a conductive plug in the source/drain contact opening.

Providing the epitaxial source/drain structure with a wavy top profile increases a contact area between the source/drain contact and the epitaxial source/drain structure, which reduces resistance between the source/drain contact and the epitaxial source/drain structure. For example, the epitaxial source/drain structure physically contacts a bottom and sidewalls of the source/drain contact. Further, because the epitaxial source/drain structure is initially fabricated with a wavy-shape, less etching of the epitaxial source/drain structure is needed to maximize a contact area between the epitaxial source/drain structure and the source/drain contact, which preserves quality of the epitaxial source/drain structure (e.g., a volume of the epitaxial source/drain structure and/or a doping profile of the epitaxial source/drain structure is less affected by source/drain contact fabrication). Different embodiments may have different advantages, and no particular advantage is required of any embodiment.

Details of the proposed epitaxial source/drain structures for multigate devices and methods of fabrication thereof are described herein in the following pages.

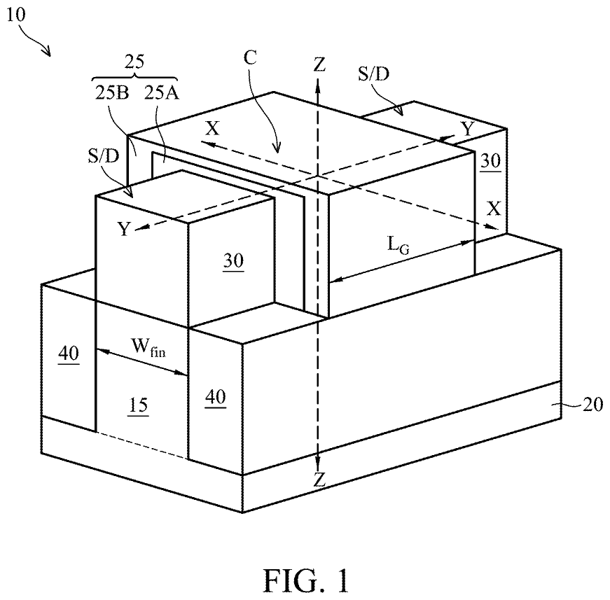

For advanced IC technology nodes, non-planar transistors, such as FinFETs and GAA transistors (collectively referred to as multigate devices), have become a popular and promising candidate for high performance and low leakage applications. FIG. 1 is a fragmentary perspective view of an exemplary multigate device 10, in portion or entirety, according to various aspects of the present disclosure. Multigate device 10 is a FinFET that includes a fin 15 extending from a substrate 20. Fin 15 has a length along a y-direction, a width along an x-direction (W_{fin}), and a height along a z-direction. The FinFET further includes a gate stack 25 and epitaxial source/drains 30. In FIG. 1, fin 15 has a non-recessed portion disposed between recessed portions, gate stack 25 wraps and engages the non-recessed portion of fin 15 (e.g., gate stack 25 is disposed on a top and opposing sidewalls of the non-recessed portion of fin 15), and epitaxial source/drains 30 are disposed over the recessed portions of fin 15 (e.g., epitaxial source/drains 30 are disposed on tops of the recessed portions of fin 15). The FinFET has a channel region (C) disposed between source/drain regions (S/D), where the channel region is provided by the non-recessed portion of fin 15 and the source/drain regions are provided by epitaxial source/drains 30 and underlying recessed portions of fin 15. During operation of the FinFET, current can flow through the channel region (e.g., non-recessed portion of fin 15) and between the source/drain regions (e.g., epitaxial source/drains 30).

Gate stack 25 has a gate length (LG) along the y-direction. In the depicted embodiment, gate stack 25 includes a gate dielectric 25A and a gate electrode 25B. In some embodiments, gate spacers are disposed along sidewalls of gate stack 25, and the gate spacers may wrap the non-recessed portion of fin 15. A substrate isolation feature 40, such as a shallow trench isolation (STI) structure, electrically isolates the FinFET from other devices and/or regions of multigate device 10. Substate isolation feature 40 is disposed over substrate 20, along sidewalls of the recessed portions of fin 15, and along sidewalls of lower portions of the non-recessed portion of fin 15. Gate stack 25 extends over the top of substrate isolation feature 40. In some embodiments, substrate isolation feature 40 surrounds a lower portion of fin 15. In some embodiments, fin 15 is not recessed in the source/drain regions of the FinFET, and epitaxial source/drains 30 wrap fin 15 (e.g., epitaxial source/drains 30 are disposed on tops and opposing sidewalls of fin 15). In some embodiments, dielectric sidewall spacers, such as fin sidewall spacers disposed over substrate isolation feature 40 and along a portion of sidewalls of fin 15 and gate spacers disposed over substrate isolation feature 40 and along sidewalls of gate stack 25, are formed before epitaxial source/drains 30. FIG. 1 has been simplified for the sake of clarity to better understand the inventive concepts of the present disclosure. Additional features can be added in multigate device 10, and some of the features described below can be replaced, modified, or eliminated in other embodiments of multigate device 10.

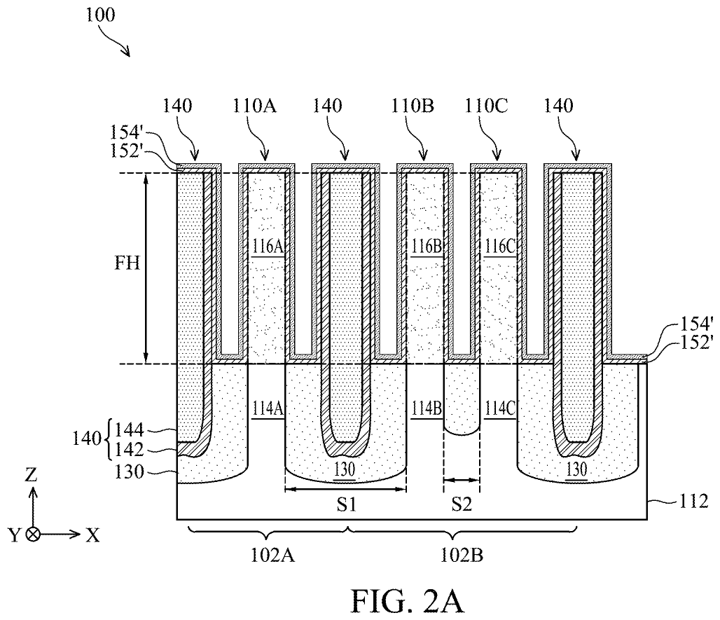

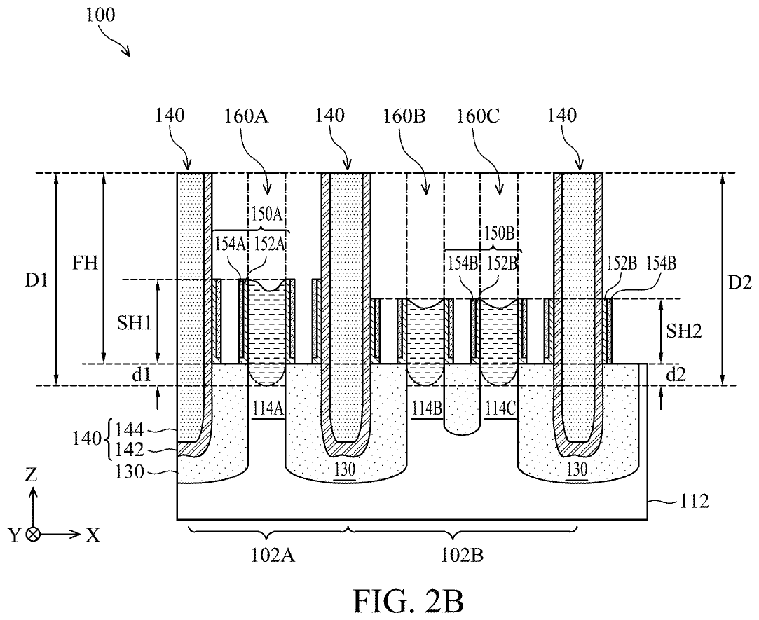

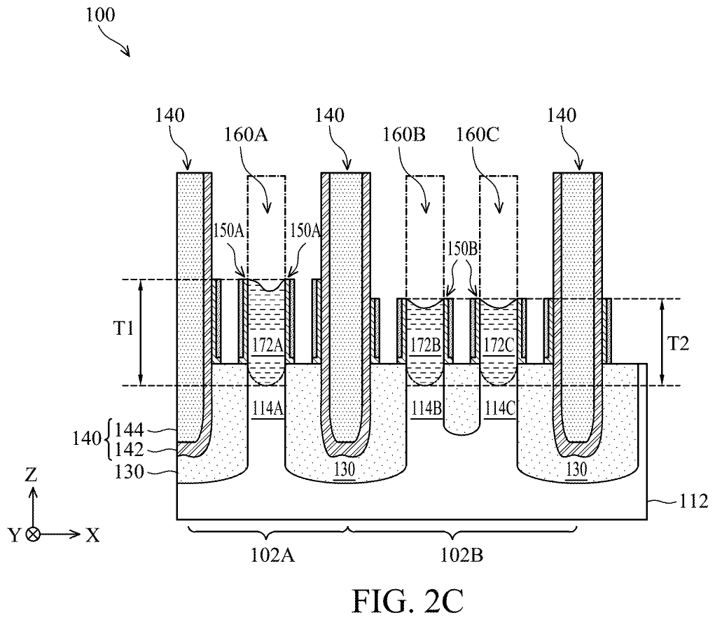

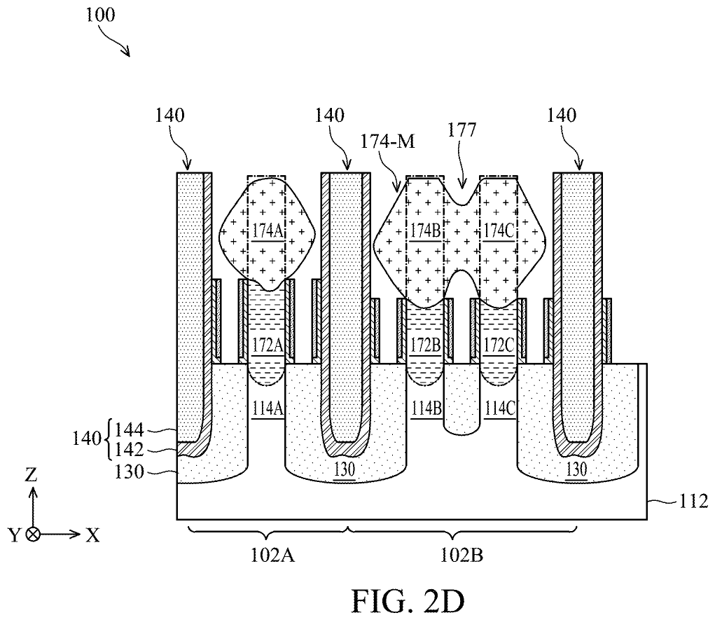

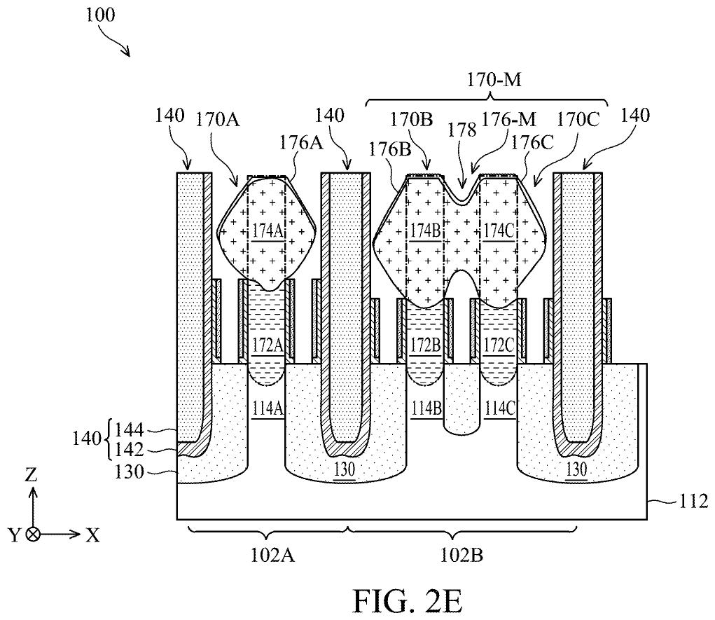

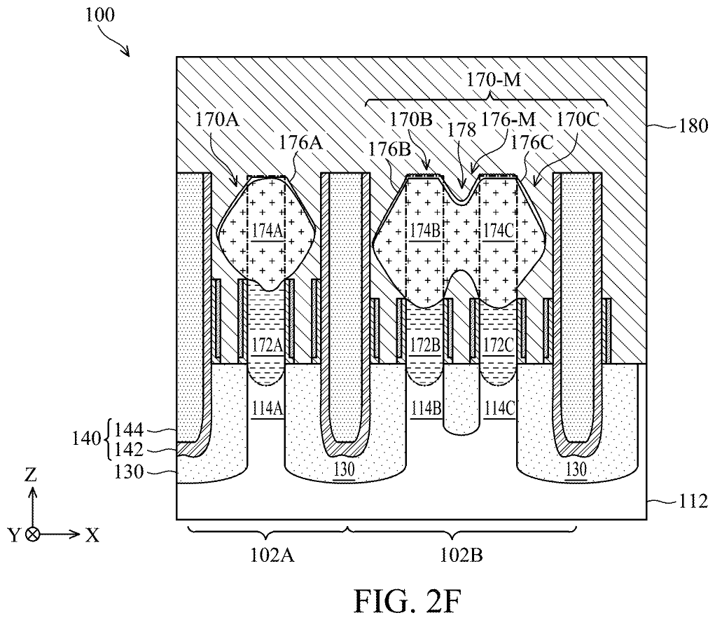

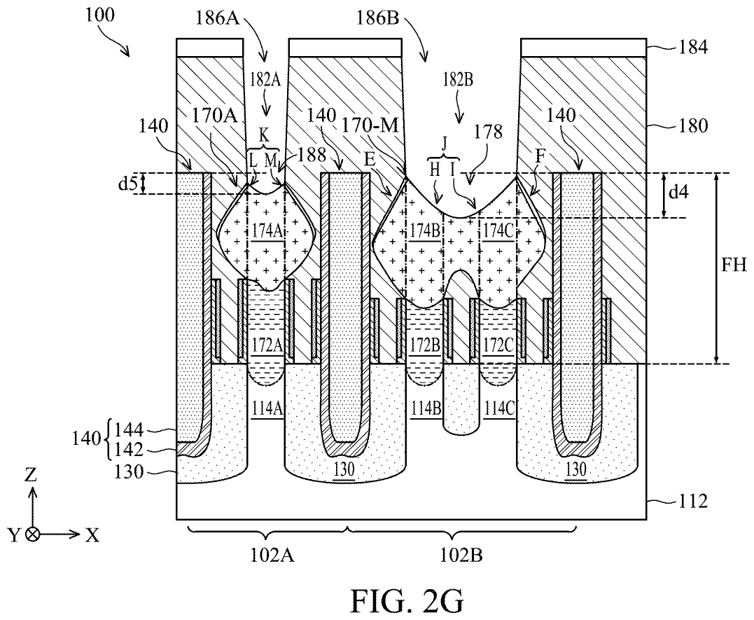

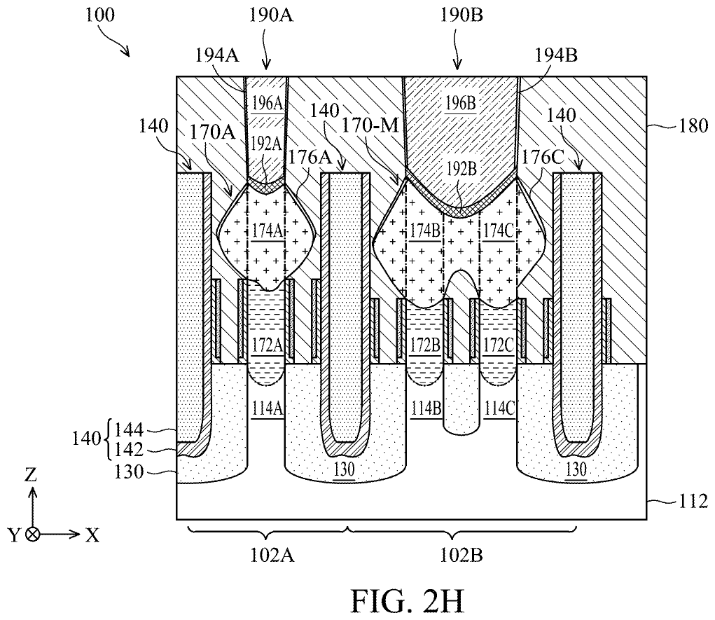

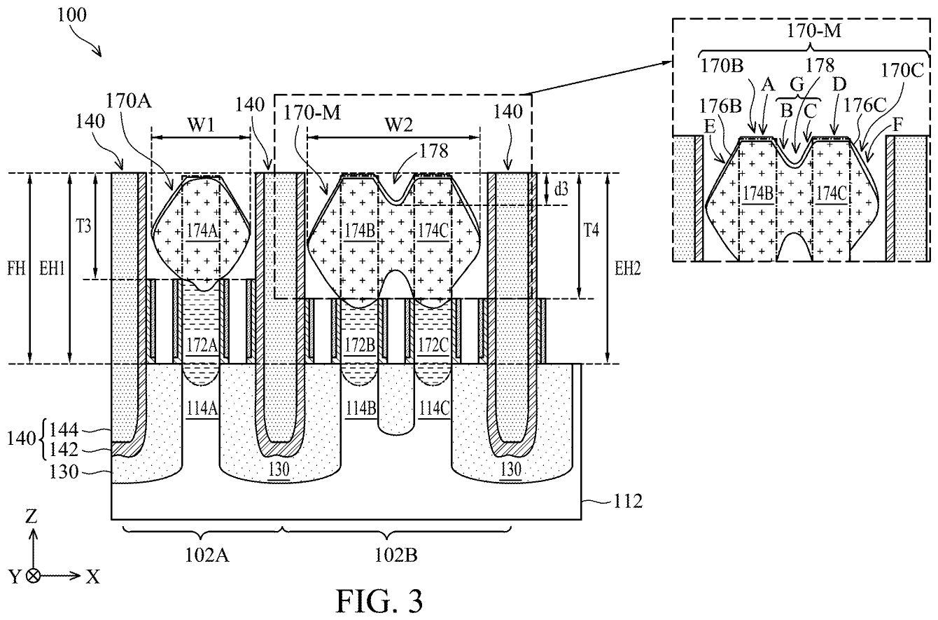

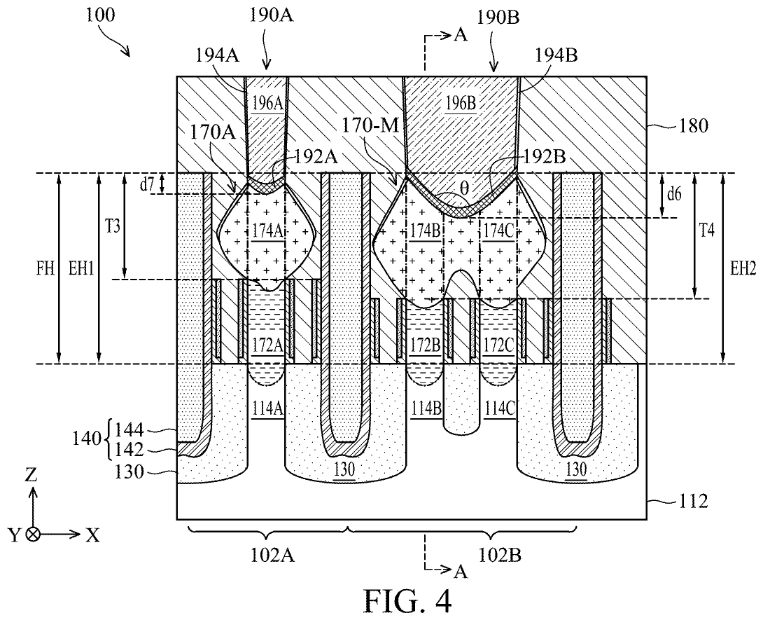

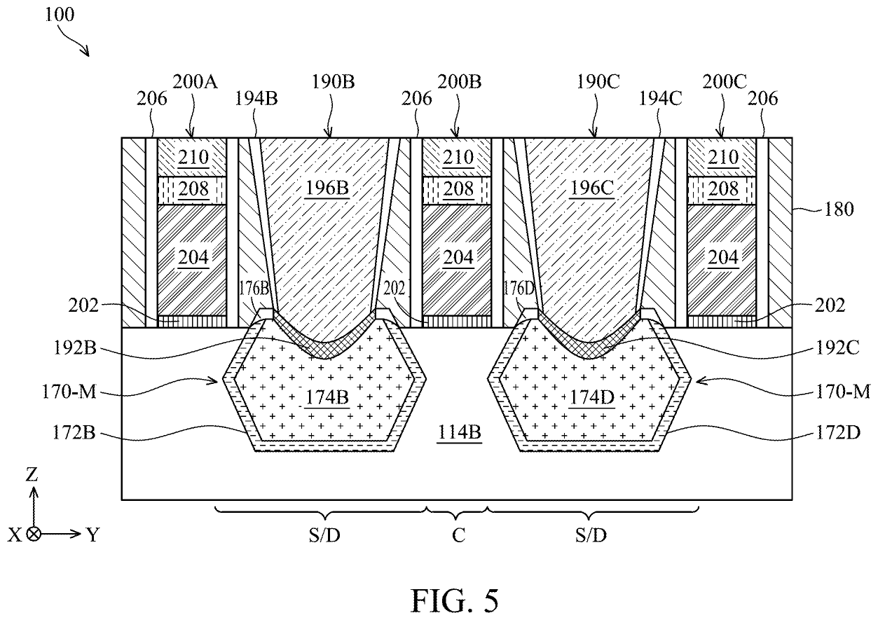

FIGS. 2A-2H are fragmentary cross-sectional views of a multigate device 100, in portion or entirety, at various fabrication stages according to various aspects of the present disclosure. Multigate device 100 includes at least one FinFET, which generally refers to a transistor having a channel formed from at least one semiconductor fin. The channel is disposed between a source and a drain, and a gate of the transistor wraps the at least one semiconductor fin. For example, the gate is on three sides of the channel, as opposed to one side of the channel as in a planar transistor. The cross-sectional views of FIGS. 2A-2H can be obtained by “cutting” multigate device 100 along the x-direction shown in FIG. 1, and thus, the cross-sectional views in FIGS. 2A-2H may be referred to as x-cut views. Further, the x-cut views are taken through source/drain regions of FinFETs of multigate device 100 (i.e., portions of the FinFETs that include, for example, epitaxial source/drains and are located outside gates/channel regions of the FinFETs and thus are not wrapped by the gates). Hence, gates of the FinFETs of multigate device 100 are not directly visible in FIGS. 2A-2H. FIGS. 2A-2H have been simplified for the sake of clarity to better understand the inventive concepts of the present disclosure. FIG. 3 is an enlarged view of multigate device 100, in portion or entirety, at the fabrication stage of FIG. 2E according to various aspects of the present disclosure. FIG. 4 is an enlarged view of the multigate device 100, in portion or entirety, at the fabrication stage of FIG. 2H according to various aspects of the present disclosure. FIG. 5 is an enlarged view of the multigate device 100, in portion or entirety, at the fabrication stage of FIG. 2H, which is a cross-sectional view taken along line B-B of FIG. 4, according to various aspects of the present disclosure. Source/drain may refer to a source and/or a drain, individually or collectively, dependent upon the context. Additional features can be added in multigate device 100, and some of the features described below can be replaced, modified, or eliminated in other embodiments of multigate device 100.

Turning to FIG. 2A, multigate device 100 has a single-fin device region 102A and a multi-fin device region 102B. In single-fin device region 102A, each FinFET formed therein includes a single fin, where a channel of the FinFET is formed in the single fin. In multi-fin device region 102B, each FinFET formed therein includes multiple fins, where a channel of the FinFET is formed in the multiple fins. For example, a fin 110A, a fin 110B, and a fin 110C extend from a substrate 112, where single-fin device region 102A includes one fin (e.g., fin 110A) and multi-fin device region 102B includes two fins (e.g., fin 110B and fin 110C). Fins 110A-110C are oriented substantially parallel to each other, extend lengthwise along a y-direction (i.e., length is along the y-direction, width is along the x-direction, and height is along the z-direction), and are spaced from each other along the x-direction. In FIG. 2A, a spacing S1 is between fins of single-fin FinFETs and multi-fin FinFETs and a spacing S2 is between fins of multi-fin FinFETs. For example, fin 110A and fin 110B are separated by spacing S1 and fin 110B and fin 110C are separated by spacing S2. In the depicted embodiment, spacing S1 is greater than spacing S2. In some embodiments, spacing S1 is about 40 nm to about 60 nm. In some embodiments, spacing S2 is about 10 nm to about 20 nm. In some embodiments, spacing S1 is about equal to spacing S2. In some embodiments, spacing S2 is less than spacing S1.

Fins 110A-110C and/or substrate 112 include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GalnAs, GaInP, GaInAsP, or combinations thereof; or combinations thereof. In some embodiments, substrate 112 is a silicon substrate, and fins 110A-110C include silicon, germanium, silicon germanium, other suitable semiconductor material, or combinations thereof. In some embodiments, fins 110A-110C are a portion of substrate 112, such as a portion of a material layer of substrate 112. For example, where substrate 112 includes silicon, fins 110A-110C are silicon fins. In some embodiments, fins 110A-110C are semiconductor layers disposed on substrate 112. In some embodiments, fins 110A-110C include the same material (e.g., fins 110A-110C are silicon fins). In some embodiments, fins 110A-110C include different materials. In some embodiments, compositions of fins 110A-110C are configured based on a type of FinFET to which fins 110A-110C belong. For example, fins 110A-110C may provide silicon germanium fins of p-type FinFETs or silicon fins of n-type FinFETs. In some embodiments, substrate 112 is a semiconductor-on-insulator substrate, such as a silicon-on-insulator (SOI) substrate, a silicon germanium-on-insulator (SGOI) substrate, or a germanium-on-insulator (GOI) substrate.

In the depicted embodiment, fins 110A-110C include substrate extensions 114A-114C, respectively, and semiconductor fins 116A-116C, respectively. Substrate extensions 114A-114C are extensions of substrate 112, and semiconductor fins 116A-116B are semiconductor layers disposed on substrate extensions 114A-114C, respectively. In some embodiments, fins 110A-110C belong to p-type FinFETs, substrate extensions 114A-114C are silicon fins, and semiconductor fins 116A-116C are silicon germanium fins.

Multigate device 100 further includes various dielectric structures, such as substrate isolation features 130, isolation fins 140, fin spacers 150A (FIG. 2B), and fin spacers 150B (FIG. 2B). Fin spacers 150A have spacer layers 152A and spacer layers 154A, which are respectively formed from a spacer layer 152′ and a spacer layer 154′ (FIG. 2A) as described below, and fin spacers 150B have spacer layers 152B and spacer layers 154B, which are respectively formed from spacer layer 152′ and spacer layer 154′ (FIG. 2A). Substrate isolation features 130, isolation fins 140, fin spacers 150A, fin spacers 150B, and later-formed isolation layers electrically isolate device regions, such as single-fin device region 102A and multi-fin device region 102B, and/or device features, such as epitaxial source/drains of FinFETs thereof.

Substrate isolation features 130 are disposed in substrate 112 and electrically isolate fins 110A-110C from one another. In FIG. 2A, substrate isolation features 130 are disposed between substrate extensions 114A-114C of fins 110A-110C, cover sidewalls of substrate extensions 114A-114C, and fill spacings between fins 110A-110C, such as spacing S1 and spacing S2. Fins 110A-110C have a fin height FH along the z-direction between top surfaces of substrate isolation features 130 and top surfaces of fins 110A-110C (which are provided by semiconductor fins 116A-116C in the depicted embodiment). In some embodiments, fin height FH is about 30 nm to about 80 nm. Fins 110A-110C having fin heights greater than 80 nm may undesirably bend and/or collapse and fins 110A-110C having fin heights less than 30 nm may provide FinFETs with insufficient carrier transport characteristics (and thus lower than desired drive currents). In FIG. 2A, substrate isolation features 130 have different depths in substate 112, where the depths are between top surfaces of substrate extensions 114A-114C and bottom surfaces of substrate isolation features 130. For example, a depth of substrate isolation features 130 filling spacing S1 is greater than a depth of substrate isolation features 130 filling spacing S2. In such embodiments, a height of substrate extension 114A along the z-direction is greater than heights of substrate extensions 114B, 114C along the z-direction. In some embodiments, substrate isolation features 130 have substantially the same depths in substrate 112 and heights of substrate extensions 114A-114C along the z-direction are substantially the same.

Substrate isolation features 130 include silicon, oxygen, nitrogen, carbon, other suitable isolation and/or dielectric constituent, or combinations thereof. For example, substrate isolation features 130 include silicon oxide, silicon nitride, silicon oxynitride, other suitable isolation material, or combinations thereof. Substrate isolation features 130 are configured as shallow trench isolation (STI) structures, deep trench isolation (DTI) structures, local oxidation of silicon (LOCOS) structures, other suitable isolation structures, or combinations thereof. In the depicted embodiment, substrate isolation features 130 are STI structures. In some embodiments, substrate isolation features 130 are oxide layers. In some embodiments, substrate isolation features 130 have multi-layer structures, such as bulk dielectric layers over dielectric liners. For example, substrate isolation features 130 include oxide layers over silicon nitride liners. In another example, substrate isolation features 130 include dielectric layers over doped liners, such as boron silicate glass (BSG) liners and/or phosphosilicate glass (PSG) liners.

Isolation fins 140 are positioned between and electrically isolate epitaxial source/drains of different FinFETs from one another, such as epitaxial source/drains of a single-fin FinFET in single-fin device region 102A and epitaxial source/drains of a multi-fin FinFET in multi-fin device region 102B. Isolation fins 140 may further electrically isolate fins 110A-110C, such as substrate extensions 114A-114C thereof, from one another. In FIG. 2A, fin 110A of a single-fin FinFET of single-fin device region 102A is between respective isolation fins 140, and fins of a multi-fin FinFET (e.g., fin 110B and fin 110C) of multi-fin device region 102B are between respective isolation fins 140. Isolation fins 140 are disposed over and extend into substrate isolation features 130, such that isolation fins 140 extend below top surfaces of substrate isolation features 130. In the depicted embodiment, isolation fins 140 further extend below top surfaces of substrate extensions 114A-114C of fins 110A-110C.

Isolation fins 140 include silicon, oxygen, nitrogen, carbon, other suitable isolation and/or dielectric constituent, or combinations thereof. For example, isolation fins 140 include silicon oxide, silicon nitride, silicon oxynitride, silicon carbonitride, silicon nitride, silicon oxycarbonitride, other suitable isolation material, or combinations thereof. The present disclosure contemplates various configurations of isolation fins. For example, isolation fins 140 can have multi-layer structures, such as bulk dielectric layers (e.g., oxide layers) disposed over dielectric liners (e.g., silicon carbonitride (SiCN) liners). In some embodiments, isolation fins 140 include lower dielectric portions and upper dielectric portions, where the lower dielectric portions and the upper dielectric portions are configured differently. In some embodiments, the lower portions include dielectric layers (e.g., oxide layers) disposed over dielectric liners. In some embodiments, the upper portions includes high-k dielectric layers.

Spacer layer 152′ and spacer layer 154′ include silicon, oxygen, carbon, nitrogen, other suitable isolation and/or dielectric constituent, or combinations thereof. For example, spacer layer 152′ and spacer layer 154′ include silicon oxide, silicon nitride, silicon oxynitride, silicon carbonitride, silicon nitride, silicon oxycarbonitride, other suitable isolation material, or combinations thereof. Spacer layer 152′ and spacer layer 154′ include different materials, such as silicon nitride and/or silicon oxide and silicon oxycarbonitride, respectively. Spacer layer 152′ and spacer layer 154′ are disposed along sidewalls and tops of semiconductor fins 116A-116C of fins 110A-110C (i.e., spacer layer 152′ and spacer layer 154′ wrap fins 110A-110C), along sidewalls and tops of isolation fins 140 (i.e., spacer layer 152′ and spacer layer 154′ wrap isolation fins 140), and along tops of substrate isolation features 130. Spacer layer 152′ and spacer layer 154′ partially fill spacings between fin 110A and respective isolation fins 140, a spacing between fin 110B and respective isolation fin 140, a spacing between fin 110C and respective isolation fin 140, and a spacing between fin 110B and fin 110C.

Turning to FIG. 2B, a source/drain recess etch is performed to form source/drain recesses (trenches) 160A-160C, respectively, in source/drain regions of fins 110A-110C. For example, semiconductor fins 116A-116C and substrate extensions 114A-114C are removed to form source/drain recesses 160A-160C. After the source/drain recess etch, fins 110A-110C have recessed portions in source/drain regions and non-recessed portions in channel regions (which are depicted with dashed lines in FIG. 2B). Recessed portions are provided by remainders of substrate extensions 114A-114C, and non-recessed portions are provided by semiconductor fins 116A-116C and semiconductor extensions 114A-114C.

Source/drain recesses 160A-160C have different dimensions in single-fin device region 102A and multi-fin device region 102B. For example, source/drain recess 160A has a depth D1 along the z-direction and extend a depth d1 along the z-direction into substrate extension 114A and below tops of substrate isolation features 130, and source/drain recess 160B and source/drain recess 160C each have a depth D2 along the z-direction and extend a depth d2 along the z-direction into substrate extensions 114B, 114C and below tops of substrate isolation features 130. Depth D1 is a sum of fin height FH and depth d1, and depth D2 is a sum of fin height FH and a depth d2. Depth D1 is between the top surface of the non-recessed portion of fin 110A and bottom of source/drain recess 160A, and depth D2 is between top surfaces of non-recessed portions of fins 110B, 110C and bottoms of source/drain recesses 160B, 160C. Depth d1 is between top surfaces of substrate isolation features 130 and bottom of source/drain recess 160A, and depth d2 is between top surfaces of substrate isolation features 130 and bottom of source/drain recesses 160B, 160C. In the depicted embodiment, depth D1 is greater than depth D2, and depth d1 is greater than depth d2. In some embodiments, depth D1 is less than or equal to depth D2 and/or depth d1 is less than or equal to depth d2.

In some embodiments, depth D1 is about 50 nm to about 90 nm. In some embodiments, depth D2 is about 45 nm to about 85 nm. Since volumes and/or dimensions of epitaxial source/drains depend on source/drain recess depth (e.g., epitaxial source/drain volume increases as source/drain recess depth increases), source/drain recesses that are too shallow (e.g., depth D1 less than 50 nm and/or depth D2 less than 45 nm) may provide epitaxial source/drains with smaller than desired volumes, such as volumes that cannot impart desired strain to channel regions of the FinFETs and/or volumes that undesirably limit FinFET drive current. Source/drain recesses that are too deep (e.g., depth D1 greater than 90 nm and/or depth D2 greater than 85 nm) may provide epitaxial source/drains that extend too far into substrate 112, such as to an implanted region (e.g., n-well and/or p-well) therein, which can cause undesired short channel effects (SCEs) in multigate device 100. In some embodiments, a difference between depth D1 and depth D2 is about 1 nm to about 5 nm. In other words, source/drain recess 160A is about 1 nm to about 5 nm deeper than source/drain recesses 160B, 160C. Differences between depth D1 and depth D2 that are less than 1 nm indicate that source/drain recess 160A may be too shallow and/or source/drain recesses 160B, 160C may be too deep, such that epitaxial source/drains in single-fin device region 102A may have volumes that provide insufficient strain to channel regions and/or epitaxial source/drains in multi-fin device region 102B extend too deep into substrate 112 (e.g., to an implanted region of substrate 112). Differences between depth D1 and depth D2 that are greater than 5 nm indicate that source/drain recess 160A may be too deep and/or source/drain recesses 160B, 160C may be too shallow, such that epitaxial source/drains in single-fin device region 102A may extend too deep into substrate 112 (e.g., to an implanted region of substrate 112) and/or epitaxial source/drains in multi-fin device region 102B may have volumes that provide insufficient strain to channel regions.

The source/drain recess etch is a dry etch, a wet etch, other suitable etching process, or combinations thereof. The source/drain recess etch selectively removes fins 110A-110C with respect to substrate isolation features 130, isolation fins 140, spacer layer 152′, spacer layer 154′, or combinations thereof. In other words, the source/drain recess etch substantially removes fins 110A-110C but does not remove, or does not substantially remove substrate isolation features 130, isolation fins 140, spacer layer 152′, spacer layer 154′, or combinations thereof. For example, an etchant is selected for the source/drain recess etch that etches semiconductor materials (e.g., fins 110A-110C) at a higher rate than dielectric materials (e.g., substrate isolation features 130, isolation fins 140, spacer layer 152′, spacer layer 154′, or combinations thereof). In some embodiments, the source/drain recess etch implements an etchant that can remove both semiconductor fins 116A-116C and substrate extensions 114A-114C. In some embodiments, the source/drain recess etch is a multi-step etch process. For example, the source/drain recess etch may use different etchants to separately remove semiconductor fins 116A-116C and substrate extensions 114A-114C.

In the depicted embodiment, fins of single-fin FinFETs and fins of two-fin FinFETs are etched at the same time (i.e., fins 110A-110C are etched simultaneously). In some embodiments, fins of single-fin FinFETs and fins of two-fin FinFETs are etched separately using different etching processes. In some embodiments, fins of p-type FinFETs and fins of n-type FinFETs are etched at the same time. In some embodiments, fins of p-type FinFETs and fins of n-type FinFETs are etched separately using different etching processes. For example, where single-fin device region 102A and multi-fin device region 102B are p-type FinFET regions, a first etching process may be performed on fins 110A-110C to form source/drain recesses 160A-160C and a second etching process may be performed on other fins of multigate device 100 to form source/drain recesses in n-type FinFET regions. In such embodiments, the n-type FinFET regions may be covered by a mask (patterning) layer (e.g., a hard mask layer and/or a resist layer) during the first etching process, and single-fin device region 102A and multi-fin device region 102B may be covered by a mask layer during the second etching process.

In FIG. 2B, a spacer etch is performed to form fin spacers 150A (having spacer layers 152A and spacer layers 154A) in single-fin device region 102A and fin spacers 150B (having spacer layers 152B and spacer layers 154B) in multi-fin device region 102B. For example, spacer layer 152′ and spacer layer 154′ are removed from horizontally-oriented surfaces of multigate device 100 (e.g., tops of isolation fins 140 and tops of substrate isolation features 130) and etched back along vertically-oriented surfaces of multigate device 100 (e.g., sidewalls of fins 110A-110C and sidewalls of isolation fins 140). Remainders of spacer layer 152′ form spacer layers 152A and spacer layers 152B of fin spacers 150A and fin spacer 150B, respectively. Remainders of spacer layer 154′ form spacer layers 154A and spacer layers 154B of fin spacers 150A and fin spacers 150B, respectively. The spacer etch is a dry etch, a wet etch, other suitable etching process, or combinations thereof. The spacer etch selectively removes spacer layer 152′ and spacer layer 154′ with respect to substrate isolation features 130, isolation fins 140, fins 110A-110C, or combinations thereof. In some embodiments, the spacer etch and the source/drain recess etch are separate, sequential etch processes. For example, the spacer etch is performed before the source/drain recess etch. In such example, the spacer etch may unintentionally or intentionally remove portions of fins 110A-110C in the source/drain regions, thereby beginning formation of source/drain recesses 160A-160C (e.g., the spacer etch may partially remove semiconductor fins 116A-116C). In some embodiments, the spacer etch and the source/drain recess etch are a single etch process.

Fin spacers 150A and fin spacers 150B have different dimensions. For example, fin spacers 150A have a height SH1 along the z-direction and fin spacers 150B have a height SH2 along the z-direction. Height SH2 is less than height SH1, which can facilitate merging of epitaxial source/drains in multi-fin device region 102B. In some embodiments, height SH1 is about 15 nm to about 30 nm. In some embodiments, height SH2 is about 5 nm to about 15 nm. Dimensions and/or volumes of epitaxial source/drains of multigate device 100 depend on fin spacer height. For example, fin spacer heights that are too small (e.g., height SH1 less than 15 nm and/or height SH2 less than 5 nm) may result in epitaxial source/drains having reduced carrier collection. In another example, fin spacer heights that are too large (e.g., height SH1 greater than 30 nm and/or height SH2 greater than 15 nm) may limit growth of epitaxial source/drains (e.g., by confining lateral dimensions thereof), which may provide epitaxial source/drains with smaller than desired volumes, such as volumes that cannot impart desired strain to channel regions of the FinFETs and/or volumes that undesirably limit FinFET drive current. In some embodiments, a ratio of height SH1 to height SH2 is about 1 to about 2 (i.e., 1≤SH1/SH2≤2). A ratio of height SH1 to height SH2 that is less than 1 indicates that height SH1 is too short and/or height SH2 is too tall, while a ratio of height SH1 to height SH2 that is greater than 2 indicates that height SH1 is too tall and/or height SH2 is too short. In some embodiments, height SH2 is greater than or equal to height SH1. In some embodiments, height SH1, height SH2, widths of fin spacers 150A, widths of fin spacers 150B, or combinations thereof are configured to control and/or facilitate desired shapes and/or profiles of subsequently formed epitaxial source/drains.

Turning to FIGS. 2C-2E and FIG. 3, an epitaxial source/drain 170A is formed in source/drain recess 160A, an epitaxial source/drain 170B is formed in source/drain recess 160B, and an epitaxial source/drain 170C is formed in source/drain recess 160C. Such processing can include epitaxially growing first semiconductor layers in source/drain recesses, such as epitaxial layers 172A-172C in source/drain recesses 160A-160C (FIG. 2C); epitaxially growing second semiconductor layers over the first semiconductor layers in the source/drain recesses, such as epitaxial layers 174A-174C in source/drain recesses 160A-160C (FIG. 2D); and epitaxially growing third semiconductor layers over the second semiconductor layers in the source/drain recesses, such as epitaxial layers 176A-176C in source/drain recesses 160A-160C (FIG. 2E and FIG. 3). Epitaxial source/drain 170A includes epitaxial layer 172A, epitaxial layer 174A, and epitaxial layer 176A; epitaxial source/drain 170B includes epitaxial layer 172B, epitaxial layer 174B, and epitaxial layer 176B; epitaxial source/drain 170C includes epitaxial layer 172C, epitaxial layer 174C, and epitaxial layer 176C. Epitaxial source/drain 170B and epitaxial source/drain 170C combine to form a merged epitaxial source/drain 170-M.

Epitaxial layers 172A-172C, epitaxial layers 174A-174C, epitaxial layers 176A-176C, or combinations thereof can be formed by epitaxy processes that implement chemical vapor deposition (CVD) techniques (for example, vapor-phase epitaxy (VPE), ultra-high vacuum CVD (UHV-CVD), low pressure CVD (LPCVD), plasma-enhanced CVD (PECVD), etc.), molecular beam epitaxy, other suitable selective epitaxy growth (SEG) process, or combinations thereof. In some embodiments, epitaxial layers 172A-172C, epitaxial layers 174A-174C, epitaxial layers 176A-176C, or combinations thereof are formed by a respective selective CVD process, such as remote plasma CVD (RPCVD). A respective selective CVD process may introduce a silicon-containing precursor and/or a germanium-containing precursor and a carrier gas into a process chamber, where the silicon-containing precursor and/or the germanium-containing precursor interact with the composition of fins 110A-110C (e.g., substrate extensions 114A-114C and/or semiconductor fins 116A-116C), epitaxial layers 172A-172C, epitaxial layers 174A-174C, epitaxial layers 176A-176C, or combinations thereof.

The silicon-containing precursor includes SiH₄ (silane), Si₂H₆, Si₂H₂Cl₂ (dichlorosilane (DCS)), SiHCl₃, SiCl₄, other suitable silicon-containing precursor, or combinations thereof. The germanium-containing precursor includes GeH₄, Ge₂H₆, GeCl₄, GeCl₂, other suitable germanium-containing precursor, or combinations thereof. The carrier gas may be an inert gas, such as H₂ and/or N₂. In some embodiments, a dopant-containing precursor is introduced into the process chamber to facilitate in-situ doping of epitaxial layers 172A-172C, epitaxial layers 174A-174C, epitaxial layers 176A-176C, or combinations thereof. The dopant-containing precursor includes boron (e.g., B₂H₆), phosphorous (e.g., PH₃), arsenic (e.g., AsH₃), other suitable dopant-containing precursor, or combinations thereof. In some embodiments, epitaxial layers 172A-172C, epitaxial layers 174A-174C, epitaxial layers 176A-176C, or combinations thereof are doped by an ion implantation process after deposition. In some embodiments, an etchant-containing precursor is introduced into the process chamber to prevent or limit growth of semiconductor material on dielectric surfaces and/or non-semiconductor surfaces. In such embodiments, CVD process parameters are tuned to ensure net deposition of semiconductor material on semiconductor surfaces. The etchant-containing precursor can include Cl₂, HCl, other etchant-containing precursor that can facilitate desired semiconductor material growth selectivity, or combinations thereof. In some embodiments, annealing processes are performed to activate dopants in epitaxial layers 172A-172C, epitaxial layers 174A-174C, epitaxial layers 176A-176C, other source/drain regions (e.g., lightly doped source/drain (LDD) regions and/or heavily doped source/drain (HDD) regions), or combinations thereof.

In FIG. 2C, epitaxial layers 172A-172C grow from fins 110A-110C, respectively, and partially fill source/drain recesses 160A-160C, respectively. Epitaxial layers 172A-172C can be referred to as shielding layers, such as where epitaxial layers 172A-172C are configured to prevent and/or reduce extrusion of dopants and/or other constituents of epitaxial layers 174A-174C, respectively, into channel regions of multigate device 100, such as into non-recessed portions of fins 110A-110C. In some embodiments, epitaxial layers 172A-172C are configured to reduce SCEs. Epitaxial layers 172A-172C are disposed over substrate extensions 114A-114C of fins 110A-110C, respectively, and fill portions of source/drain recesses 160A-160C between fin spacers 150A or fin spacers 150B. Epitaxial layers 172A-172C do not extend above their respective fin spacers 150A or fin spacers 150B. For example, tops of epitaxial layers 172A-172C are at about or slightly recessed from tops of fin spacers 150A or fin spacers 150B. For example, epitaxial layer 172A has a thickness T1 along the z-direction, epitaxial layers 172B, 172C have a thickness T2 along the z-direction, thickness T1 is about equal to a sum of depth d1 and height SH1 of fin spacers 150A, and thickness T2 is about equal to a sum of depth d2 and height SH2 of fin spacers 150B. In the depicted embodiment, thickness T1 is greater than thickness T2. In some embodiments, thickness T1 is less than the sum of depth d1 and height SH1. In some embodiments, thickness T2 is less than the sum of depth d2 and height SH2. In some embodiments, thickness T1 is greater than the sum of depth d1 and height SH1. In some embodiments, thickness T2 is greater than the sum of depth d2 and height SH2.

Epitaxial layers 172A-172C include silicon, germanium, silicon germanium, other suitable semiconductor material, or combinations thereof. In the depicted embodiment, where single-fin device region 102A and multi-fin device region 102B are p-type FinFET regions, epitaxial layers 172A-172C include p-doped silicon germanium. The p-type dopant is boron, indium, other suitable p-type dopant, or combinations thereof. In some embodiments, epitaxial layers 172A-172C have a germanium concentration of about 25 atomic percent (at %) to about 40 at %. Epitaxial layers 172A-172C having germanium concentrations that are too low (e.g., less than 25 at %) may not impart desired strain to channel regions of the FinFETs and/or undesirably limit FinFET drive current, while epitaxial layers 172A-172C having germanium concentrations that are too high (e.g., greater than 40 at %) may decrease dopant solid solubility (i.e., decrease achievable amount of active dopant in epitaxial source/drains 170A-170C, thus limiting channel strain and/or drive current). In some embodiments, epitaxial layers 172A-172C have a boron dopant concentration of about 1×10²⁰ atoms/cm³ (cm⁻³) to about 8×10²⁰ cm⁻³. Epitaxial layers 172A-172C having boron concentrations that are too low (e.g., less than 1×10²⁰ cm⁻³) may not effectively function as shielding layers (e.g., epitaxial layers 172A-172C may not prevent dopant from diffusing from epitaxial source/drains 170A-170C into channel regions, such as non-recessed portions of fins 110A-110C), while dopants in epitaxial layers 172A-172C having boron concentrations that are too high (e.g., greater than 8×10²⁰ cm⁻³) may undesirably diffuse into the channel regions and cause SCEs in multigate device 100.

Epitaxial layers 172A-172C have any suitable germanium concentration profile and any suitable dopant profile, such as any suitable boron dopant profile. In some embodiments, epitaxial layers 172A-172C have a substantially uniform (constant) germanium profile and/or substantially uniform boron dopant profile along thickness T1 or thickness T2. For example, a germanium concentration and/or a boron concentration is substantially the same from bottoms to tops of epitaxial layers 172A-172C. In some embodiments, epitaxial layers epitaxial layers 172A-172C have a gradient germanium profile and/or a gradient boron profile along thickness T1 or thickness T2. For example, a germanium concentration and/or a boron concentration increases from bottoms to tops of epitaxial layers 172A-172C (e.g., from about 25 at % to about 40 at % and/or from about 1×10²⁰ cm⁻³ to about 8×10²⁰ cm⁻³, respectively). In another example, a germanium concentration and/or a boron concentration decreases from bottoms to tops of epitaxial layers 172A-172C (e.g., from about 40 at % to about 25 at % and/or from about 8×10²⁰ cm⁻³ to about 1×10²⁰ cm⁻³, respectively). In some embodiments, epitaxial layers 172A-172C have a banded germanium and/or boron profile, a stair germanium and/or boron profile, a linear continuous germanium and/or boron profile, a non-linear continuous germanium and/or boron profile, a bell-curved germanium and/or boron profile, a saw-tooth germanium and/or boron profile, other germanium and/or boron suitable, etc.

In FIG. 2D, epitaxial layers 174A-174C grow from epitaxial layers 172A-172C, respectively, and/or semiconductor fins 116A-116C of fins 110A-110C, respectively. Epitaxial layers 174A-174C substantially fill remainders of source/drain recesses 160A-160C, respectively. Epitaxial layers 174A-174C include silicon, germanium, silicon germanium, other suitable semiconductor material, or combinations thereof. In the depicted embodiment, where single-fin device region 102A and multi-fin device region 102B are p-type FinFET regions, epitaxial layers 174A-174C include p-doped silicon germanium. The p-type dopant is boron, indium, other suitable p-type dopant, or combinations thereof. A germanium concentration and a dopant concentration of epitaxial layers 174A-174C is greater than a germanium concentration and a dopant concentration, respectively, of epitaxial layers 172A-172C. Epitaxial layers 174A-174C can thus be referred to as heavily doped regions of epitaxial source/drains 170A-170C, respectively. In some embodiments, epitaxial layers 174A-174C have a germanium concentration of about 35 at % to about 60 at %. Epitaxial layers 174A-174C having germanium concentrations that are too low (e.g., less than 35 at %) may not impart desired strain to channel regions of the FinFETs and/or undesirably limit FinFET drive current, while epitaxial layers 174A-174C having germanium concentrations that are too high (e.g., greater than 60 at %) may decrease dopant solid solubility (i.e., decrease achievable amount of active dopant in epitaxial source/drains 170A-170C, thus limiting channel strain and/or drive current). In some embodiments, epitaxial layers 174A-174C have a boron dopant concentration of about 8×10²⁰ cm⁻³ to about 3×10²¹ cm⁻³. Epitaxial layers 174A-174C having boron concentrations that are too low (e.g., less than 8×10²⁰ cm⁻³) may have lower than desired numbers of active charge carriers, thereby degrading device performance (e.g., lower drive current), while boron concentrations that are too high (e.g., greater than 3×10²¹ cm⁻³) may result in the dopants (i.e., boron) bonding with more atoms, which can undesirably decrease an amount of active dopants in epitaxial layers 174A-174C and thereby degrade device performance.

Epitaxial layers 174A-174C have any suitable germanium concentration profile and any suitable dopant profile, such as any suitable boron dopant profile. In some embodiments, epitaxial layers 174A-174C have a substantially uniform (constant) germanium profile and/or substantially uniform boron dopant profile along thickness T3 or thickness T4. For example, a germanium concentration and/or a boron concentration is substantially the same from bottoms to tops of epitaxial layers 174A-174C. In some embodiments, epitaxial layers 174A-174C have a gradient germanium profile and/or a gradient boron profile along thickness T3 or thickness T4. For example, a germanium concentration and/or a boron concentration increases from bottoms to tops of epitaxial layers 174A-174C (e.g., from about 35 at % to about 60 at % and/or from about 8×10²⁰ cm⁻³ to about 3×10²¹ cm⁻³, respectively). In another example, a germanium concentration and/or a boron concentration decreases from bottoms to tops of epitaxial layers 174A-174C. In some embodiments, epitaxial layers 174A-174C have a banded germanium and/or boron profile, a stair germanium and/or boron profile, a linear continuous germanium and/or boron profile, a non-linear continuous germanium and/or boron profile, a bell-curved germanium and/or boron profile, a saw-tooth germanium and/or boron profile, other germanium and/or boron suitable, etc. In some embodiments, epitaxial layers 174A-174C have a boron concentration that increases along their thickness from epitaxial layers 172A-172C to a maximum boron concentration and then decreases along their thickness from the maximum boron concentration to a lower boron concentration at top surfaces thereof.

When forming epitaxial layers 174A-174C, epitaxial growth/deposition conditions are tuned to achieve merging of epitaxial layer 174B and epitaxial layer 174C and thereby provide multi-fin device region 102B with a merged epitaxial layer 174-M. The merger is controlled to form a recess (trough) 177 in merged epitaxial layer 174-M. Recess 177 is located between fin 110B and fin 110C and forms a portion of merged epitaxial layer 174-M that will provide a source/drain contact landing area for a source/drain contact. As discussed herein, recess 177 increases a top surface area of merged epitaxial layer 174-M and thus increases a contact area between merged epitaxial source/drain 170-M and a source/drain contact subsequently formed thereto. In FIG. 2D, a negatively sloped surface of epitaxial layer 174B meets and combines with a positively sloped surface of epitaxial layer 174C to form recess 177 having a substantially U-shaped profile and/or a substantially V-shaped profile. The negatively sloped surface of epitaxial layer 174B extends downward from a top of epitaxial layer 174B towards substrate 112, and the positively sloped surface of epitaxial layer 174C extends downward from a top of epitaxial layer 174C towards substrate 112. In some embodiments, the sloped surfaces of epitaxial layer 174B and epitaxial layer 174C are (111) facets thereof.

A low temperature epitaxial growth process implements more than one silicon-containing precursor and/or more than one germanium-containing precursor to promote growth of epitaxial layer 174B and epitaxial layer 174C as depicted and provide merged epitaxial layer 174-M with recess 177 therein. In some embodiments, multiple silicon-containing precursors (e.g., Si₂H₂Cl₂ and SiH₄), a germanium-containing precursor (e.g., Ge₂H₆ or GeH₄), a carrier precursor (e.g., H₂), and a dopant precursor (e.g., B₂H₆ or BCl₃) are introduced into a process chamber. The silicon-containing precursors provide different growth rates in different directions, and an amount and/or a flow rate of the silicon-containing precursors can be tuned to promote merging of epitaxial layer 174B and epitaxial layer 174C and sloping of surfaces thereof in a manner that forms recess 177. For example, in a first direction, a growth rate of silicon germanium facilitated by Si₂H₂Cl₂ may be greater than a growth rate of silicon germanium facilitated by SiH₄, while in a second direction, the growth rate of silicon germanium facilitated by SiH₄ may be greater than the growth rate of silicon germanium facilitated by Si₂H₂Cl₂. In such example, a flow rate of Si₂H₂Cl₂, a flow rate of SiH₄, a flow rate of the germanium-containing precursor, a flow rate of the dopant precursor, a flow rate of the carrier precursor, or combinations thereof can be adjusted to control growth rates of silicon germanium along the first direction and the second direction and thus control a shape and/or a profile of merged epitaxial layer 174-M. In the depicted embodiment, growth rates of the silicon germanium in the first direction and the second direction are turned to form recess 177 in merged epitaxial layer 174-M. In some embodiments, a ratio of the flow rate of Si₂H₂Cl₂ and the flow rate of SiH₄ (and thus a ratio of an amount of Si₂H₂Cl₂ to an amount of SiH₄) is controlled to tune a growth rate and a shape and/or a profile of merged epitaxial layer 174-M and epitaxial layers 174A-174C.

To further promote merging of epitaxial layer 174B and epitaxial layer 174C and sloping of surfaces thereof in a manner that forms recess 177, the epitaxial growth process is a low temperature process, such as low temperature RPCVD, performed at a temperature less than about 600° C. In some embodiments, an epitaxial growth/deposition temperature of about 400° C. to about 600° C. promotes formation of recess 177 in merged epitaxial layer 174-M. When the epitaxial growth process is performed at temperatures less than 400° C., hydrogen content in epitaxial layers 174A-174C may be too high and undesirably alter performance characteristics of the FinFETs (e.g., drive currents and/or threshold voltages thereof). When the epitaxial growth process is performed at temperatures greater than 600° C., crystallinity of epitaxial layers 174A-174C may be degraded and/or epitaxial material may not grow in a manner that provides downward sloping surfaces as depicted. Limiting a thermal budget of the epitaxial growth process (e.g., to less than about 600° C.) can also provide better control of strain in epitaxial layers 174A-174C, which can improve overall device quality, for example, by minimizing bending of fins 110A-110C (e.g., as a result of too much strain and/or relaxation), minimizing relaxation of epitaxial source/drains 170A-170C and/or channel regions of the FinFETs, which can reduce generation of defects therein, etc. In some embodiments, the epitaxial growth temperature is about 500° C. to about 550° C. In some embodiments, the epitaxial growth process is performed at a pressure of about 10 torr to about 50 torr. Epitaxial growth/deposition pressures that are too low (e.g., less than 10 torr) may provide inadequate growth rates (e.g., minimal silicon germanium growth or silicon germanium growth rates that are too slow) and/or provide epitaxial layers 174A-174C with hydrogen contents that are too high. Epitaxial growth/deposition pressures that are too high (e.g., greater than 50 torr) may degrade uniformity of epitaxial layers 174A-174C, such as uniformity in contents and/or growth rates thereof.

In some embodiments, an etchant precursor (e.g., HCl) is also introduced into the process chamber to further control the growth rate and the shape and/or the profile of epitaxial layers 174A-174C and merged epitaxial layer 174-M. In such embodiments, a flow rate of an etch gas and/or a ratio of the etch gas relative to other deposition gas constituents (e.g., silicon-containing deposition gas and/or germanium-containing deposition gas) can be tuned to optimize the growth rate and the shape and/or the profile of epitaxial layers 174A-174C and merged epitaxial layer 174-M. In some embodiments, the etchant precursor and parameters associated therewith are tuned to control strain of and/or provided by epitaxial layers 174A-174C and merged epitaxial layer 174-M. In some embodiments, flow rates of the silicon-containing precursors, a flow rate of the germanium-containing precursor, a flow rate of the dopant precursor, a flow rate of the etchant precursor, a flow rate of the carrier precursor, ratios thereof, an epitaxial growth temperature, an epitaxial growth pressure, an epitaxial growth time, other suitable epitaxial growth parameter, or combinations thereof are tuned to provide desired growth rates, shapes, profiles, germanium concentrations, silicon concentrations, boron concentrations, hydrogen concentrations, strain characteristics, other characteristics, or combinations thereof of epitaxial layers 174A-174C and/or merged epitaxial layer 174-M.

In FIG. 2E, epitaxial layers 176A-176C can grow from and are disposed over epitaxial layers 174A-174C, respectively. In the depicted embodiment, epitaxial layer 176B and epitaxial layer 176C combine to form merged epitaxial layer 176-M. Since epitaxial layers 176A-176C conform to shapes and/or profiles of epitaxial layers 174A-174C, merged epitaxial source/drain 170-M has a recess 178 that is substantially similar to recess 177. For example, recess 178 is substantially U-shaped or substantially V-shaped. In FIG. 2E and FIG. 3, recess 178 is defined by merged epitaxial layer 176-M, and since merged epitaxial layer 176-M partially fills recess 177, dimensions of recess 178 (e.g., depth along the z-direction, width along the x-direction, etc.) may be slightly smaller than recess 177. Epitaxial layers 176A-176C and merged epitaxial layer 176-M can be referred to as capping layers. In some embodiments, epitaxial layers 176A-176C function as capping layers that protect epitaxial layers 174A-174C (i.e., heavily doped portions of epitaxial source/drains 170A-170C), respectively, during subsequent processing, such as processing associated with fabricating source/drain contacts.

Epitaxial layers 176A-176C include silicon, germanium, silicon germanium, other suitable semiconductor material, or combinations thereof. In the depicted embodiment, where single-fin device region 102A and multi-fin device region 102B are p-type FinFET regions, epitaxial layers 176A-176C include p-doped silicon germanium. In some embodiments, epitaxial layers 176A-176C have a germanium concentration of about 45 at % to about 55 at %. Since higher germanium content at or near a surface of epitaxial source/drains 170A-170C can reduce source/drain contact resistance, epitaxial layers 176A-176C having germanium concentrations that are too low (e.g., less than 45 at %) may not minimize such contact resistance, and in some instances, may undesirably increase such resistance. Epitaxial layers 176A-176C having germanium concentrations that are too high (e.g., greater than 55 at %) may be over-etched during source/drain contact formation, leading to dopant loss in epitaxial source/drains 170A-170C that can leave defects therein (e.g., voids) and/or undesirably modify their characteristics (e.g., reduce strain thereof and/or strain imparted thereby). A p-type dopant concentration of epitaxial layers 176A-176C is less than a p-type dopant concentration of epitaxial layers 174A-174C. In some embodiments, epitaxial layers 176A-176C have a boron dopant concentration of about 1×10₂₁ cm⁻³ to about 2×10₂₁ cm⁻³. Dopant concentration of epitaxial layers 176A-176C that is too low (e.g., less than 1×10²¹ cm⁻³) can negatively impact silicide formation during source/drain contact fabrication (e.g., degrade quality of silicide and/or impeded its formation). If a dopant concentration of epitaxial layers 176A-176C is too high (e.g., greater than 2×10²¹ cm⁻³), dopant (e.g., boron) may extrude into surrounding device features, such as gates of the FinFETs, and undesirably modify electrical characteristics of the FinFETs (e.g., threshold voltages thereof) and/or device features thereof. Epitaxial layers 176A-176C have any suitable germanium concentration profile and any suitable dopant profile.

In FIG. 2E and FIG. 3, merged epitaxial source/drain 170-M has a top surface area that is greater than a top surface area of conventional merged epitaxial source/drains. For example, instead of having a substantially flat top surface, merged epitaxial source/drain 170-M has a wavy top surface that includes a trough between two crests. For example, the wavy top surface includes a facet (surface) A, a facet B, a facet C, a facet D, a facet E, and a facet F. Facet A and facet D are topmost surfaces of epitaxial source/drain 170B and epitaxial source/drain 170C, respectively, and facet A and facet D that are substantially flat and extend substantially horizontally (e.g., along the x-direction). Facet B and facet F are negatively sloped surfaces of epitaxial source/drain 170B and epitaxial source/drain 170C, respectively, and extend downwardly and laterally right from facet A and facet D, respectively, towards substrate 112. Facet C and facet E are positively sloped surfaces of epitaxial source/drain 170C and epitaxial source/drain 170B, respectively, and extend downwardly and laterally left from facet D and facet A, respectively, towards substrate 112. Facet B of epitaxial source/drain 170B and facet C of epitaxial source/drain 170C meet and combine to form a concave surface G that defines recess 178 of merged epitaxial source/drain 170-M. The trough of merged epitaxial source/drain 170-M is therefore provided by a lowest point of recess 178 and the crests of merged epitaxial source/drain 170-M are provided by highest points of facet A and facet D.

Recess 178 extends a depth d3 below tops of non-recessed portions of fins 110A-110C (which provide channel regions of the FinFETs). In some embodiments, depth d3 is about 5 nm to about 15 nm. If depth d3 is too shallow (e.g., less than 5 nm), a contact area between merged epitaxial source/drain 170-M and a subsequently formed source/drain contact may not sufficiently reduce source/drain contact resistance. In other words, any reduction in source/drain contact resistance provided by wavy-shaped merged epitaxial source/drain 170-M having depth d3 less than 5 nm is negligible. If depth d3 is too deep (e.g., greater than 15 nm), merged epitaxial source/drain 170-M may have a smaller than desired volume, such as a volume that cannot impart desired strain to channel regions of the FinFET and/or a volume that undesirably limits FinFET drive current. Further, if depth d3 is too deep (e.g., greater than 15 nm), merged epitaxial source/drain 170-M may be susceptible to dopant loss during source/drain contact formation (e.g., etching and/or silicide formation may reduce a volume of heavily doped portions (e.g., epitaxial layers 174B, 174C) of merged epitaxial source/drain 170-M too much).

Epitaxial source/drain 170A has an epitaxial height EH1 along the z-direction and merged epitaxial source/drain 170-M has an epitaxial height EH2 along the z-direction. Epitaxial height EH1 is between top surfaces of substrate isolation features 130 and a top surface of epitaxial source/drain 170A, and epitaxial height EH2 is between top surfaces of substrate isolation features 130 and a top surface of merged epitaxial source/drain 170-M. In the depicted embodiment, epitaxial height EH1 and epitaxial height EH2 are about equal to fin height FH, such that tops of epitaxial source/drain 170A, tops of merged epitaxial source/drain 170-M, and tops of non-recessed portions of fins 110A-110C (i.e., channel regions thereof) are about the same height above substrate isolation features 130. In such embodiments, epitaxial height EH1 and epitaxial height EH2 are the same. In some embodiments, epitaxial height EH1 and epitaxial height EH2 are different. In some embodiments, epitaxial height EH1 and/or epitaxial height EH2 is less than fin height FH. In some embodiments, epitaxial height EH1 and/or epitaxial height EH2 is greater than fin height FH. For example, a difference between epitaxial height EH1 and/or epitaxial height EH2 and fin height FH is about 1 nm to about 5 nm. In other words, epitaxial source/drain 170A and/or merged epitaxial source/drain 170-M extend about 1 nm to about 5 nm above fins 110A-110C. If epitaxial source/drains extend too high above fins 110A-110C, subsequently formed interconnects may undesirably contact the epitaxial source/drains. For example, a source/drain via, which connects a source/drain contact to an overlying routing (metallization) layer, may undesirably contact an epitaxial source/drain extending more than 5 nm above fins 110A-110C, which can cause an electrical short.

Epitaxial source/drain 170A and merged epitaxial source/drain 170-M have upper portions and lower portions. Upper portions extend above fin spacers 150A and/or fin spacers 150B. Lower portions are confined by and/or extend below fin spacers 150A and/or fin spacers 150B. In the depicted embodiment, the upper portion of epitaxial source/drain 170A includes epitaxial layer 174A and epitaxial layer 176A, and the upper portion of merged epitaxial source/drain 170-M includes epitaxial layer 174B, epitaxial layer 174C, epitaxial layer 176B, and epitaxial layer 176C. In some embodiments, the upper portion of epitaxial source/drain 170A also includes epitaxial layer 172A. In some embodiments, the upper portion of merged epitaxial source/drain 170-M also includes epitaxial layer 172B and/or epitaxial layer 172C.

A height of epitaxial source/drain 170A over fin spacers 150A corresponds with a thickness T3 of the upper portion of epitaxial source/drain 170A along the z-direction, and a height of merged epitaxial source/drain 170-M over fin spacers 150B corresponds with a thickness T4 of the upper portion of merged epitaxial source/drain 170-M along the z-direction. Thickness T3 is between tops of fin spacers 150A and a top of epitaxial source/drain 170A. Thickness T4 is between tops of fin spacers 150B and a top of merged epitaxial source/drain 170-M. In the depicted embodiment, thickness T4 is greater than thickness T3. In some embodiments, thickness T3 is about 20 nm to about 30 nm. In some embodiment, thickness T4 is about 35 nm to about 45 nm. Epitaxial source/drains having heights above fin spacers that are too small (e.g., thickness T3 less than 20 nm and/or thickness T4 less than 35 nm) may have smaller than desired volumes, such as volumes that cannot impart desired strain to channel regions of the FinFETs and/or volumes that undesirably limit FinFET drive current. Epitaxial source/drains having heights above fin spacers that are too large (e.g., thickness T3 greater than 30 nm and/or thickness T4 greater than 45 nm) may have larger than desired volumes and/or extend too far above the fin spacers and/or the isolation fins, which can result in overlying interconnects inadvertently contacting the epitaxial source/drains. For example, source/drain vias may contact epitaxial source/drains, resulting in electrical shorts.

In some embodiments, a difference between thickness T4 and thickness T3 is about 5 nm to about 15 nm. When the difference between thickness T4 and thickness T3 is less than 5 nm, merged epitaxial source/drain 170-M may be too short and/or epitaxial source/drain 170A may be too tall, such that epitaxial source/drains in multi-fin device region 102B may have volumes that are too small and thus provide insufficient strain to channel regions, such as described herein, and/or epitaxial source/drains in single-fin device region 102A may have volumes that are too large and thus may be susceptible to electrical shorting, such as described herein. When the difference between thickness T4 and thickness T3 is greater than 15 nm, merged epitaxial source/drain 170-M may be too tall and/or epitaxial source/drain 170A may be too short, such that epitaxial source/drains in multi-fin device region 102B may have volumes that are too large and thus may be susceptible to electrical shorting, such as described herein, and/or epitaxial source/drains in single-fin device region 102A may have volumes that are too small and thus provide insufficient strain to channel regions, such as described herein.

Epitaxial source/drain 170A has a width W1 along the x-direction and merged epitaxial source/drain 170-M has a width W2 along the x-direction. Width W1 is a maximum (greatest) width of epitaxial source/drain 170A, and width W2 is a maximum (greatest) width of merged epitaxial source/drains 170-M. In other words, width W1 and width W2 are between outermost sidewalls of epitaxial source/drain 170A and merged epitaxial source/drain 170-M, respectively. Width W2 is greater than width W1. In some embodiments, width W1 is about 30 nm to about 40 nm. In some embodiment, width W2 is about 60 nm to about 80 nm. Epitaxial source/drains having widths that are too small (e.g., width W1 less than 30 nm and/or width W2 less than 60 nm) may have smaller than desired volumes, such as volumes that cannot impart desired strain to channel regions of the FinFETs and/or volumes that undesirably limit FinFET drive current. Epitaxial source/drains having widths that are too large (e.g., width W1 greater than 40 nm and/or width W2 greater than 80 nm) may have larger than desired volumes and/or extend too far above the fin spacers and/or the isolation fins, which can result in overlying interconnects inadvertently contacting the epitaxial source/drains. For example, source/drain vias may contact epitaxial source/drains, resulting in electrical shorts.

In some embodiments, a ratio of width W2 to width W1 is about 2 to about 3 (i.e., 2≤W2/W1≤3). When the ratio of width W2 to width W1 is less than 2, merged epitaxial source/drain 170-M may be too small (or narrow) to provide a sufficient source/drain contact landing area (which can increase source/drain contact resistance in multi-fin device region 102B and/or increase sensitivity of multi-fin device region 102B to source/drain contact overlay/alignment issues during fabrication) and/or epitaxial source/drain 170A may be too large (or wide) for fin pitches and/or fin spacings of advanced technology nodes, resulting in unintentional merging of epitaxial source/drain 170A with other epitaxial source/drains and/or device features and/or device defects (e.g., epi residue). When the ratio of width W2 to width W1 is greater than 3, merged epitaxial source/drain 170-M may be too large for fin pitches and/or fin spacings of advanced technology nodes, resulting in unintentional merging of merged epitaxial source/drain 170-M with other epitaxial source/drains and/or device features and/or device defects (e.g., epi residue), and/or epitaxial source/drain 170A may be too small to provide a sufficient source/drain contact landing area (which can increase source/drain contact resistance in single-fin device region 102A and/or increase sensitivity of single-fin device region 102A to source/drain contact overlay/alignment issues during fabrication).

Turning to FIG. 2F, a dielectric layer 180 (for example, a contact etch stop layer (CESL) and an interlayer dielectric (ILD) layer) is formed over multigate device 100. Dielectric layer 180 is disposed over epitaxial source/drain 170A, merged epitaxial source/drain 170-M, and isolation fins 140. In the depicted embodiment, dielectric layer 180 fills spaces between epitaxial source/drain 170A and isolation fins 140, spaces between fin spacers 150A, spaces between merged epitaxial source/drain 170-M and isolation fins 140, and spaces between fin spacers 150B. Forming dielectric layer 180 can include one or more deposition processes and a CMP process and/or other planarization process, which may be performed until reaching (exposing) a gate structure (e.g., a dummy gate). The deposition process(es) can include CVD, PVD, ALD, RPCVD, PECVD, HDPCVD, FCVD, HARP, LPCVD, ALCVD, APCVD, SACVD, MOCVD, other suitable methods, or combinations thereof. In some embodiments, ILD layer is formed by FCVD, HARP, HDPCVD, or combinations thereof.

ILD layer includes a dielectric material including, for example, silicon oxide, carbon doped silicon oxide, silicon nitride, silicon oxynitride, TEOS-formed oxide, PSG, BSG, BPSG, FSG, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other suitable dielectric material, or combinations thereof. In some embodiments, ILD layer includes a dielectric material having a dielectric constant that is less than a dielectric constant of silicon dioxide (e.g., k<3.9). In some embodiments, ILD layer includes a dielectric material having a dielectric constant that is less than about 2.5 (i.e., an extreme low-k (ELK) dielectric material), such as SiO₂ (for example, porous silicon dioxide), silicon carbide (SiC), and/or carbon-doped oxide (for example, a SiCOH-based material (having, for example, Si—CH₃ bonds)), each of which is tuned/configured to exhibit a dielectric constant less than about 2.5. ILD layer can include a multilayer structure having multiple dielectric materials. CESL includes a material different than ILD layer, such as a dielectric material that is different than the dielectric material of ILD layer. For example, where ILD layer includes a dielectric material that includes silicon and oxygen and having a dielectric constant that is less than about the dielectric constant of silicon dioxide, CESL can include silicon and nitrogen, such as silicon nitride or silicon oxynitride.

Turning to FIG. 2G, a patterning process is performed on dielectric layer 180 to form a source/drain contact opening 182A and a source/drain contact opening 182B therein. Source/drain contact opening 182A extends through dielectric layer 180 and exposes epitaxial source/drain 170A, and source/drain contact opening 182B extends through dielectric layer 180 and exposes merged epitaxial source/drain 170-M. Dielectric layer 180 can be patterned by a lithography process and etching process. The lithography process can include forming a patterned mask layer 184 over dielectric layer 180, where the patterned mask layer 184 has an opening 186A therein that overlaps epitaxial source/drain 170A and an opening 186B therein that overlaps merged epitaxial source/drain 170-M (and, in particular, a portion of merged epitaxial source/drain 170-M having recess 178). The etching process can include transferring a pattern in patterned mask layer 184 to dielectric layer 180, for example, by removing portions of dielectric layer 180 exposed by opening 186A and opening 186B. The etching process is a dry etch, a wet etch, other suitable etching process, or combinations thereof. The etching process selectively removes dielectric layer 180 (i.e., dielectric material(s)) with respect to epitaxial source/drains 170A-170C (e.g., semiconductor material(s)). In some embodiments, the etching process removes patterned mask layer 184, in portion or entirety, from over dielectric layer 180. In some embodiments, after the etching process, patterned mask layer 184 is removed from over dielectric layer 180, for example, by an etching process and/or a resist stripping process.

In the depicted embodiment, a source/drain etch is performed to increase top surface area of merged epitaxial source/drain 170-M, which provides a contact landing area for a source/drain contact formed in source/drain contact opening 182B. The source/drain etch is a dry etch, a wet etch, other suitable etching process, or combinations thereof. The source/drain etch selectively removes epitaxial source/drains 170A-170C (i.e., semiconductor material(s)) with respect to dielectric layer 180 (i.e., dielectric material(s)). In some embodiments, the etching process implemented to pattern dielectric layer 180 may partially etch epitaxial source/drains 170A-170C. In some embodiments, the etching process implemented to pattern dielectric layer 180 also recesses epitaxial source/drains 170A-170C (i.e., a single etching process is performed to pattern dielectric layer 180 and increase contact landing areas).

The source/drain etch removes portions of epitaxial layer 176C, epitaxial layer 176B, epitaxial layer 174C, and epitaxial layer 174B, such that merged epitaxial source/drain 170-M has a wavy top surface that includes a facet H, a facet I, facet E, and facet F. Facet H is a negatively sloped surface of epitaxial layer 174B and extends laterally right and downward from facet E towards substrate 112. Facet I is a positively sloped surface of epitaxial layer 174C and extends laterally left and downward from facet F towards substrate 112. Facet H and facet I meet and combine to form a concave surface J that defines recess 178 after the source/drain etch, a trough of merged epitaxial source/drain 170-M is provided by a lowest point of recess 178, and crests of merged epitaxial source/drain 170-M are provided by highest points of facet E/facet H and facet F/facet I, respectively. Lengths of facet H and facet I are greater than lengths of facet B and facet C, respectively, which increases a source/drain contact landing area. In some embodiments, the source/drain etch may partially remove facet E and/or facet F. In such embodiments, the source/drain etch reduces lengths of facet E and/or facet F.

The source/drain etch further increases dimensions of recess 178, such as a width and a depth of recess 178. For example, the source/drain etch increases the depth of recess 178 from depth d3 to a depth d4 below tops of non-recessed portions of fins 110A-110C. In some embodiments, depth d4 is about 10 nm to about 20 nm. If depth d4 is too shallow (e.g., less than 10 nm), a contact area between merged epitaxial source/drain 170-M and a subsequently formed source/drain contact may not sufficiently reduce source/drain contact resistance. In other words, any reduction in source/drain contact resistance provided by wavy-shaped merged epitaxial source/drain 170-M having depth d4 less than 10 nm is negligible. If depth d4 is too deep (e.g., greater than 20 nm), merged epitaxial source/drain 170-M may have a smaller than desired volume, such as a volume that cannot impart desired strain to channel regions of the FinFET and/or a volume that undesirably limits FinFET drive current. Further, if depth d4 is too deep (e.g., greater than 20 nm), a volume of heavily doped portions (e.g., epitaxial layers 174B, 174C) of merged epitaxial source/drain 170-M may be reduced too much (i.e., dopant loss issues) and undesirably alter performance of the FinFET in multi-fin device region 102B.

The source/drain etch can also remove portions of epitaxial layer 176A and epitaxial layer 174A to provide epitaxial source/drain 170A with a concave top surface K. A negatively sloped surface of epitaxial layer 174A (e.g., facet L) and a positively sloped surface of epitaxial layer 174A (e.g., facet M) meet and combine to form concave top surface K. Concave top surface K has a contact landing area that is greater a contact landing area of epitaxial source/drain 170A having a substantially flat top surface, such as depicted in FIG. 2E. Concave top surface K forms a recess 188 of epitaxial source/drain 170A, and recess 188 extends a depth d5 below tops of non-recessed portions of fins 110A-110C. Depth d5 is less than depth d4.

Turning to FIG. 2H, FIG. 4, and FIG. 5, a source/drain contact 190A is formed in source/drain contact opening 182A and a source/drain contact 190B in source/drain contact opening 182B. Source/drain contact 190A includes a silicide layer 192A, a contact liner 194A, and a contact bulk layer 196A. Source/drain contact 190B includes a silicide layer 192B, a contact liner 194A, and a contact bulk layer 196B. A substantially V-shaped interface is between source/drain contact 190B and merged epitaxial source/drain 170-M, and a substantially U-shaped interface is between source/drain contact 190A and epitaxial source/drain 170A. Accordingly, merged epitaxial source/drain 170-M and epitaxial source/drain 170A wrap tips of source/drain contact 190B and source/drain contact 190A, respectively (which are portions of source/drain contacts 190B, 190B that extend below tops of non-recessed portions of fins 110A-110C). The V-shaped interface has a corresponding angle θ. In FIG. 2H and FIG. 4, angle θ is between a negatively sloped top surface of silicide layer 192B and a positively sloped top surface of silicide layer 192B. In some embodiments, angle θ is about 80° to about 140° to maximize a contact area between source/drain contact 190B and merged epitaxial source/drain 170-M and minimize source/drain contact resistance. For example, interface angles that are too small (e.g., less than 80°) or too large (e.g., greater than 140°) may reduce contact area between source/drain contact 190B and merged epitaxial source/drain 170-M, thereby increasing source/drain contact resistance. In some embodiments, angle θ is between facet H and facet I of merged epitaxial source/drain 170-M. In some embodiments, angle θ is between a negatively sloped bottom surface of contact bulk layer 196B and a positively sloped bottom surface of contact bulk layer 196B. In some embodiments, angle θ is between a negatively sloped bottom surface of contact liner 194B and a positively sloped bottom surface of contact liner 194B.

A silicidation process is performed to form silicide layer 192A and silicide layer 192B over epitaxial source/drain 170A and merged epitaxial source/drain 170-M, respectively. The silicidation process consumes and converts portions of epitaxial layers 174A-174C into silicide layer 192A or silicide layer 192B, which may increase depth of recess 188 and/or depth of recess 178. For example, the depth of recess 178 increases from depth d4 to a depth d6 below tops of non-recessed portions of fins 110A-110C, and the depth of recess 188 increases from depth d4 to a depth d7 below tops of non-recessed portions of fins 110A-110C. In some embodiments, depth d6 is about 15 nm to about 25 nm. In some embodiments, depth d7 is about 5 nm to about 10 nm. If depth d6 and depth d7 are too shallow (e.g., less than 15 nm and 5 nm, respectively), source/drain contacts (which may include silicide layer 192A and silicide layer 192B, respectively) may not land on and/or physically contact heavily doped regions of merged epitaxial source/drain 170-M and epitaxial source/drain 170A, respectively, and thus fail to minimize source/drain contact resistance therebetween. If depth d6 and depth d7 are too deep (e.g., greater than 25 nm and 10 nm, respectively), merged epitaxial source/drain 170-M and epitaxial source/drain 170A may have smaller than desired volumes, such as volumes that cannot impart desired strain to channel regions of the FinFETs and/or volumes that undesirably limit FinFET drive currents. Further, if depth d6 and depth d7 are too deep, volumes of heavily doped portions of merged epitaxial source/drain 170-M and epitaxial source/drain 170A may be reduced too much (i.e., dopant loss issues) and undesirably alter performance of the FinFETs. In some embodiments, the silicidation process may further consume and convert portions of epitaxial layers 176A-176C into respective silicide layers.

Depth D7 is less than depth d6. In some embodiments, a difference between depth d6 and depth d7 is about 1 nm to about 5 nm. When the depth difference is too small (e.g., less than 1 nm), merged epitaxial source/drain 170-M may have a volume that is too small for a multi-fin FinFET. When the depth difference is too large (e.g., greater than 5 nm), a source/drain contact may extend too far into merged epitaxial source/drain 170-M and below tops of non-recessed portions of fins 110A-110C, which can cause SCEs, and/or epitaxial source/drain 170A may not be sufficiently recessed from tops of non-recessed fins 110A-110C, which can result in an electrical short (e.g., where a via contacts epitaxial source/drain 170A).

In some embodiments, a thickness of silicide layer 192B is a difference of depth d6 and depth d4 (i.e., thickness of silicide layer 192B=depth d6−depth d4), and a thickness of silicide layer 192A is a difference of depth d7 and depth d5 (i.e., thickness of silicide layer 192A=depth d7−depth d5). In some embodiments, a thickness of silicide layer 192B is about 5 nm to about 10 nm. A silicide layer that is too thin (e.g., thickness is less than 5 nm) may undesirably increase a Schottky barrier height between merged epitaxial source/drain 170-M and a source/drain contact (which may include silicide layer 192B), while a silicide layer that is too thick (e.g., thickness is greater than 10 nm) may undesirably increase source/drain contact resistance, which can further lead to charge carrier reduction.

In some embodiments, the silicidation process includes depositing a metal layer over epitaxial source/drain 170A and merged epitaxial source/drain 170-M, respectively, by a suitable deposition process. The metal layer includes any metal constituent suitable for promoting silicide formation, such as nickel, platinum, palladium, vanadium, titanium, cobalt, tantalum, ytterbium, zirconium, other suitable metal, or combinations thereof. Multigate device 100 is then heated (for example, subjected to an annealing process) to cause constituents of epitaxial source/drain 170A and merged epitaxial source/drain 170-M to react with metal constituents in the metal layer. Silicide layer 192A and silicide layer 192B thus include a metal constituent and a constituent of epitaxial source/drain 170A and merged epitaxial source/drain 170-M, respectively (for example, silicon and/or germanium). In the depicted embodiment, the metal layer is a titanium-containing layer, and silicide layers 190A, 190B include titanium and silicon and can be referred to as a titanium silicide layers. Any un-reacted metal, such as remaining portions of the metal layer, is selectively removed by any suitable process.

Contact liners 194A, 194B include a dielectric material that can enhance electrical isolation of contact bulk layers 196A, 196B (e.g., contact liners 194A, 194B may include contact spacers) and/or an electrically conductive material that promotes adhesion between a dielectric material (e.g., dielectric layer 180) and contact bulk layers 196A, 196B (e.g., contact liners 194A, 194B may include barrier layers). Contact bulk layers 196A, 196B include an electrically conductive material, such as aluminum, copper, titanium, tantalum, tungsten, ruthenium, molybdenum, cobalt, iridium, palladium, platinum, nickel, tin, gold, silver, other suitable metals, alloys thereof (e.g., TiN, TaN, TaC, TaCN, TiAl, TiAlN, etc.), silicides thereof (e.g., NiSi, CoSi, CuSi, TaSiN, etc.), or combinations thereof. In some embodiments, contact bulk layers 196A, 196B include cobalt. In some embodiments, contact liners 194A, 194B and/or contact bulk layers 196A, 196B have a multilayer structure. For example, contact liners 194A, 194B may include a first sub-layer that includes titanium or tantalum and a second sub-layer that includes titanium nitride or tantalum nitride. In another example, contact liners 194A, 194B include a first sub-layer that includes a dielectric material (e.g., silicon nitride layer) and a second sub-layer that includes an electrically conductive material (e.g., metal nitride layer(s)). In some embodiments, source/drain contacts 190A, 190B do not include contact liners 194A, 194B, such as where source/drain contacts 190A, 190B are barrier-free.

Contact liners 194A, 194B and/or contact bulk layers 196A, 196B are formed by PVD, CVD, ALD, electroplating, electroless plating, other suitable deposition process, or combinations thereof. In some embodiments, contact liners 194A, 194B are conformally deposited by an ALD process or other suitable deposition process over dielectric layer 180 and silicide layers 192A, 192B, such that contact liners 194A, 194B have a substantially uniform thickness. In some embodiments, contact bulk layers 196A, 196B are formed by a non-selective deposition process, such as blanket CVD. Thereafter, any excess material(s) can be removed by a planarization process, such as a CMP process, thereby reducing thicknesses and/or planarizing top surfaces of source/drain contacts 190A, 190B and dielectric layer 180. In some embodiments, contact bulk layers 196A, 196B are formed by a bottom-up deposition process, which generally refers to a deposition process that fills an opening from bottom to top.

In FIG. 5, multigate device 100 further includes more than one merged epitaxial source/drain 170-M in substrate extension 114B (e.g., portion of fin 110B) along the y-direction, such as merged epitaxial source/drain 170-M having epitaxial layer 172B, epitaxial layer 174B, and epitaxial layer 176B and a merged epitaxial source/drain 170-M having an epitaxial layer 172D, epitaxial layer 174D, and epitaxial layer 176D. In such embodiments, a source/drain contact 190C is also formed in a respective source/drain contact opening, and source/drain contact 190C includes a silicide layer 192C, a contact liner 194C, and a contact bulk layer 196C. A tip of source/drain contact 190C is wrapped by epitaxial layer 174D of respective merged epitaxial source/drain 170-M, and a substantially V-shaped interface is between source/drain contact 190C and respective merged epitaxial source/drain 170-M.

Further, multigate device 100 includes a gate structure 200A, a gate structure 200B, and a gate structure 200C. Gate structures 200A-200C each include a gate stack (e.g., a gate dielectric 202 and a gate electrode 204) and gate spacers 206 disposed along sidewalls of the gate stack. In the X-Z plane, gate structures 200A-200C wrap and engage fin 110B (e.g., the gate stacks are disposed on tops and opposing sidewalls of fin 110B). In the Y-Z plane, gate structure 200B is disposed over a channel region (C) of fin 110B and between merged epitaxial source/drains 170-M, which are disposed in source/drain regions (S/D) of fin 110B. During operation of multigate device 100, current can flow through fin 110B (e.g., a non-recessed portion of substrate extension 114B) and between merged epitaxial source/drains 170-M by biasing gate structure 200B and/or one or both of merged epitaxial source/drains 170-M disposed in fin 110B. In some embodiments, multigate device 100 can further include metal layers 208 (e.g., tungsten layers) disposed over gate electrodes 204 and dielectric layers 210 (e.g., silicon nitride layers) disposed over metal layers 208. In such embodiments, metal layers 208 and/or dielectric layers 210 may be formed after recessing gate electrodes 204, such that metal layers 208 and dielectric layers 210 are between respective gate spacers 206.

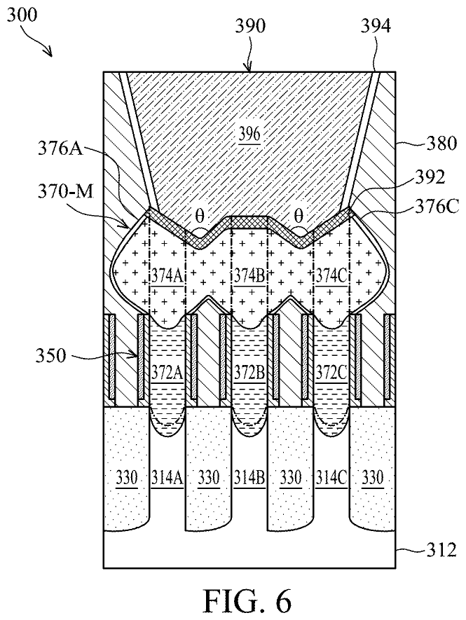

FIG. 6 is a fragmentary cross-sectional view of a multigate device 300, in portion or entirety, according to various aspects of the present disclosure. Multigate device 300 is similar in many respects to multigate device 100, except multigate device 300 has a multi-fin device region that includes a three-fin FinFET. Three-fin FinFET includes a substrate 312, substrate extensions 314A-314C (which form recessed portions of fins of the three-fin FinFET), substrate isolation features 330, fin spacers 350, and merged epitaxial source/drain 370-M, which includes epitaxial layers 372A-372C, epitaxial layers 374A-374C, and epitaxial layers 376A-376C. Because multigate device 300 includes a three-fin FinFET, merged epitaxial source/drain 370-M includes more than one recess, such as a recess formed by merged epitaxial layer 374A/epitaxial layer 376A and epitaxial layer 374B/epitaxial layer 376B and a recess formed by merged epitaxial layer 374B/epitaxial layer 376B and epitaxial layer 374C/epitaxial layer 376C. In such embodiments, a source/drain contact 390 (including, for example, a silicide layer 392, a contact liner 394, and a contact bulk layer 396) can share more than one V-shaped interface, each of which corresponds with a respective recess and has a respective corresponding angle, with merged epitaxial source/drain 370-M. FIG. 6 has been simplified for the sake of clarity to better understand the inventive concepts of the present disclosure. Additional features can be added in multigate device 300, and some of the features described below can be replaced, modified, or eliminated in other embodiments of multigate device 300.

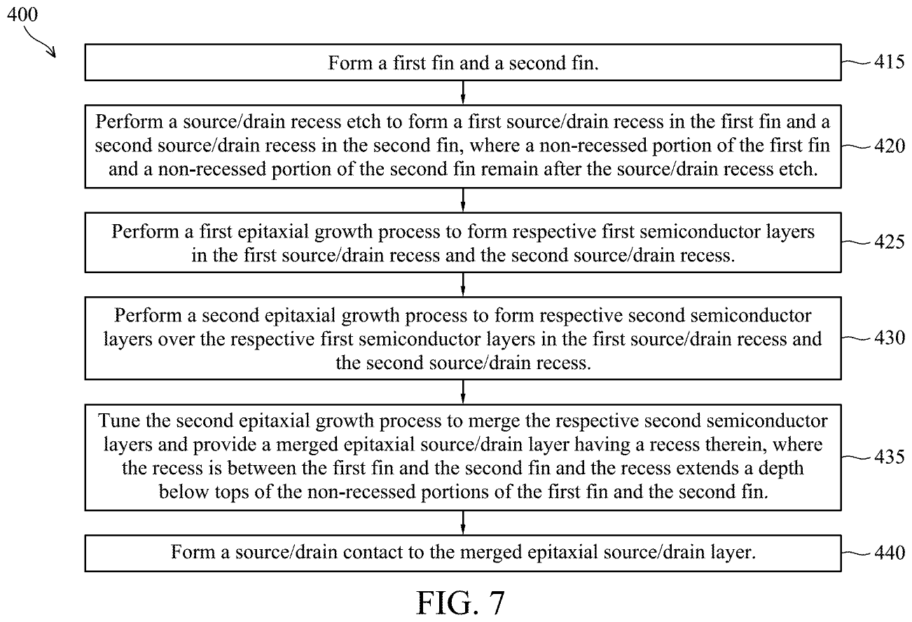

FIG. 7 is a flow chart of a method 400 for fabricating a multigate device having enhanced epitaxial source/drain structures according to various aspects of the present disclosure. At block 415, method 400 includes forming a first fin and a second fin. At block 420, a source/drain recess etch is performed to form a first source/drain recess in the first fin and a second source/drain recess in the second fin. A non-recessed portion of the first fin and a non-recessed portion of the second fin remain after the source/drain recess etch. At block 425 and block 430, a first epitaxial growth process is performed to form respective first semiconductor layers in the first source/drain recess and the second source/drain recess and a second epitaxial growth process is performed to form respective second semiconductor layers over the respective first semiconductor layers in the first source/drain recess and the second source/drain recess. At block 435, method 400 includes tuning the second epitaxial growth process to merge the respective second semiconductor layers and provide a merged epitaxial source/drain layer having a recess therein. The recess is between the first fin and the second fin and the recess extends a depth below tops of the non-recessed portions of the first fin and the second fin. At block 440, a source/drain contact is formed to the merged epitaxial source/drain layer. Additional steps can be provided before, during, and after method 400, and some of the steps described can be moved, replaced, or eliminated for additional embodiments of method 400.

Multigate device 100, multigate device 300, FinFETs thereof, or combinations thereof may be included in a microprocessor, a memory, other IC device, or combinations thereof. In some embodiments, multigate device 100 and/or multigate device 300 is a portion of an IC chip, an SoC, or portion thereof, that includes various passive and active microelectronic devices, such as resistors, capacitors, inductors, diodes, PFETs, NFETs, MOSFETs, CMOS transistors, BJTs, LDMOS transistors, high voltage transistors, high frequency transistors, other suitable components, or combinations thereof.

In some embodiments, where single-fin device region 102A and multi-fin device region 102B are n-type FinFET regions, epitaxial source/drain 170A and merged epitaxial source/drain 170-M can include n-doped silicon layers, and the n-type dopant is phosphorous, arsenic, other suitable n-type dopant, or combinations thereof. In such embodiments, a silicon-containing precursor (e.g., DCS and/or SiH₄), a carrier precursor (e.g., H₂ and/or N₂), an etchant precursor (e.g., HCl), and a dopant precursor (e.g., PH₃ and/or AsH₃) are introduced into a process chamber when depositing epitaxial layers 174A-17C.

Epitaxial source/drain structures for enhancing performance of multigate devices, such as fin-like field-effect transistors (FETs) or gate-all-around (GAA) FETs, and methods of fabricating the epitaxial source/drain structures, are disclosed herein. For example, epitaxial growth and/or depositions parameters are controlled and/or tuned to provide epitaxial source/drains with profiles that increase contact landing areas and thus contact areas between the epitaxial source/drains and source/drain contacts, which can significantly reduce source/drain contact resistance and improve overall FinFET performance.

The present disclosure provides for many different embodiments. An exemplary semiconductor structure includes a first fin and a second fin, an epitaxial source/drain structure disposed on the first fin and the second fin, and a source/drain contact disposed on the epitaxial source/drain structure. The source/drain contact and the epitaxial source/drain structure have a concave interface that is below top surfaces of the first fin and the second fin. In some embodiments, the epitaxial source/drain structure includes, a first epitaxial layer disposed on the first fin, a second epitaxial layer disposed on the second fin, a third epitaxial layer disposed on the first epitaxial layer and the second epitaxial layer, and the concave interface is between the third epitaxial layer and the source/drain contact. In some embodiments, the epitaxial source/drain structure further includes a fourth epitaxial layer disposed on the third epitaxial layer. In some embodiments, the third epitaxial layer includes a first sublayer disposed on the first fin and a second sublayer disposed on the second fin. In such embodiments, the first sublayer merges with the second sublayer and forms a trough of the epitaxial source/drain structure, and the source/drain contact fills the trough.

In some embodiments, the source/drain contact includes a silicide layer and a conductive plug, and the silicide layer is between the conductive plug and the epitaxial source/drain structure. In some embodiments, the silicide layer is V-shaped. In some embodiments, the silicide layer is below the top surfaces of the first fin and the second fin. In some embodiments, the epitaxial source/drain structure includes silicon germanium, the silicide layer includes titanium silicide, and the conductive plug includes cobalt.

An exemplary device includes a first fin and a second fin extending lengthwise along a first direction. The first fin and the second fin each have a non-recessed portion and a recessed portion. A gate extends lengthwise along a second direction that is different than the first direction. The gate wraps the non-recessed portion of the first fin and the non-recessed portion of the second fin. A merged epitaxial source/drain is on the recessed portion of the first fin and the recessed portion of the second fin. A source/drain contact is on the merged epitaxial source/drain. The source/drain contact and the merged epitaxial source/drain have a V-shaped interface therebetween and the source/drain contact extends below tops of the non-recessed portions of the first fin and the second fin. In some embodiments, the source/drain contact includes a silicide layer disposed below tops of the non-recessed portions of the first fin and the second fin. In some embodiments, an angle between a first top surface of the silicide layer and a second top surface of the silicide layer is about 80° to about 140°. In some embodiments, the source/drain contact extends to a depth below the tops of the non-recessed portions of the first fin and the second fin, and the depth is about 15 nm to about 25 nm. In some embodiments, a tip of the V-shaped interface is between the first fin and the second fin along the second direction.

In some embodiments, the source/drain contact is a first source/drain contact, and the device further includes a third fin extending lengthwise along the first direction, and the third fin has a non-recessed portion and a recessed portion. The gate wraps the non-recessed portion of the third fin, an epitaxial source/drain is on the recessed portion of the third fin, and a second source/drain contact is on the epitaxial source/drain. The second source/drain contact and the epitaxial source/drain have a U-shaped interface therebetween and the second source/drain contact extends below a top of the non-recessed portion of the third fin. In some embodiments, the first source/drain contact has a first depth below the tops of the non-recessed portions of the first fin and the second fin, the second source/drain contact has a second depth below the top of the non-recessed portion of the third fin, and the first depth is greater than a second depth.

An exemplary method includes forming a first fin and a second fin and performing a source/drain recess etch to form a first source/drain recess in the first fin and a second source/drain recess in the second fin. A non-recessed portion of the first fin and a non-recessed portion of the second fin remain after the source/drain recess etch. The method further includes performing a first epitaxial growth process to form respective first semiconductor layers in the first source/drain recess and the second source/drain recess, performing a second epitaxial growth process to form respective second semiconductor layers over the respective first semiconductor layers in the first source/drain recess and the second source/drain recess, and tuning the second epitaxial growth process to merge the respective second semiconductor layers and provide a merged epitaxial source/drain layer having a recess therein. The recess is between the first fin and the second fin and the recess extends a depth below tops of the non-recessed portions of the first fin and the second fin. The method further includes forming a source/drain contact to the merged epitaxial source/drain layer. In some embodiments, tuning the second epitaxial growth process includes implementing an epitaxial growth temperature of about 400° C. to about 600° C. In some embodiments, tuning the second epitaxial growth process includes implementing at least two silicon-comprising precursors that correspond with different growth rates in different directions. In some embodiments, the method further includes performing a source/drain etch to enlarge the recess before forming the source/drain contact. In some embodiments, tuning the second epitaxial growth process includes providing the merged epitaxial source/drain layer with a V-shaped recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first fin and a second fin;
an epitaxial source/drain structure disposed on the first fin and the second fin; and
a source/drain contact disposed on the epitaxial source/drain structure, wherein the source/drain contact and the epitaxial source/drain structure have a concave interface that is below top surfaces of the first fin and the second fin.

2. The semiconductor structure of claim 1, wherein the epitaxial source/drain structure includes:
a first epitaxial layer disposed on the first fin;
a second epitaxial layer disposed on the second fin; and
a third epitaxial layer disposed on the first epitaxial layer and the second epitaxial layer, wherein the concave interface is between the third epitaxial layer and the source/drain contact.

3. The semiconductor structure of claim 2, wherein the epitaxial source/drain structure further includes a fourth epitaxial layer disposed on the third epitaxial layer.

4. The semiconductor structure of claim 2, wherein the third epitaxial layer includes a first sublayer disposed on the first fin and a second sublayer disposed on the second fin, the first sublayer merges with the second sublayer and forms a trough of the epitaxial source/drain structure, and the source/drain contact fills the trough.

5. The semiconductor structure of claim 1, wherein the source/drain contact includes a silicide layer and a conductive plug, wherein the silicide layer is between the conductive plug and the epitaxial source/drain structure.

6. The semiconductor structure of claim 5, wherein the silicide layer is V-shaped.

7. The semiconductor structure of claim 5, wherein the silicide layer is below the top surfaces of the first fin and the second fin.

8. The semiconductor structure of claim 5, wherein the epitaxial source/drain structure includes silicon germanium, the silicide layer includes titanium silicide, and the conductive plug includes cobalt.

9. A device comprising:
a first fin and a second fin extending lengthwise along a first direction, wherein the first fin and the second fin each have a non-recessed portion and a recessed portion;
a gate extending lengthwise along a second direction that is different than the first direction, wherein the gate wraps the non-recessed portion of the first fin and the non-recessed portion of the second fin;
a merged epitaxial source/drain on the recessed portion of the first fin and the recessed portion of the second fin; and
a source/drain contact on the merged epitaxial source/drain, wherein the source/drain contact and the merged epitaxial source/drain have a V-shaped interface therebetween and the source/drain contact extends below tops of the non-recessed portions of the first fin and the second fin.

10. The device of claim 9, wherein the source/drain contact includes a silicide layer disposed below tops of the non-recessed portions of the first fin and the second fin.

11. The device of claim 10, wherein an angle between a first top surface of the silicide layer and a second top surface of the silicide layer is about 80° to about 140°.

12. The device of claim 9, wherein the source/drain contact extends to a depth below the tops of the non-recessed portions of the first fin and the second fin, wherein the depth is about 15 nm to about 25 nm.

13. The device of claim 9, wherein a tip of the V-shaped interface is between the first fin and the second fin along the second direction.

14. The device of claim 9, wherein the source/drain contact is a first source/drain contact, the device further comprising:
a third fin extending lengthwise along the first direction, wherein the third fin has a non-recessed portion and a recessed portion;
the gate wraps the non-recessed portion of the third fin;
an epitaxial source/drain on the recessed portion of the third fin; and
a second source/drain contact on the epitaxial source/drain, wherein the second source/drain contact and the epitaxial source/drain have a U-shaped interface therebetween and the second source/drain contact extends below a top of the non-recessed portion of the third fin.

15. The device of claim 14, wherein:
the first source/drain contact has a first depth below the tops of the non-recessed portions of the first fin and the second fin;
the second source/drain contact has a second depth below the top of the non-recessed portion of the third fin; and
the first depth is greater than a second depth.

16. A method comprising:
forming a first fin and a second fin;
performing a source/drain recess etch to form a first source/drain recess in the first fin and a second source/drain recess in the second fin, wherein a non-recessed portion of the first fin and a non-recessed portion of the second fin remain after the source/drain recess etch;
performing a first epitaxial growth process to form respective first semiconductor layers in the first source/drain recess and the second source/drain recess;
performing a second epitaxial growth process to form respective second semiconductor layers over the respective first semiconductor layers in the first source/drain recess and the second source/drain recess;
tuning the second epitaxial growth process to merge the respective second semiconductor layers and provide a merged epitaxial source/drain layer having a recess therein, wherein the recess is between the first fin and the second fin and the recess extends a depth below tops of the non-recessed portions of the first fin and the second fin; and
forming a source/drain contact to the merged epitaxial source/drain layer.

17. The method of claim 16, the tuning the second epitaxial growth process includes implementing an epitaxial growth temperature of about 400° C. to about 600° C.

18. The method of claim 16, wherein the tuning the second epitaxial growth process includes implementing at least two silicon-comprising precursors that correspond with different growth rates in different directions.

19. The method of claim 16, further comprising performing a source/drain etch to enlarge the recess before forming the source/drain contact.

20. The method of claim 16, wherein the tuning the second epitaxial growth process includes providing the merged epitaxial source/drain layer with a V-shaped recess.
